(19) United States
(12) Patent Application Publication
(10) Pub. No.: US 2025/0167044 A1
(43) Pub. Date: May 22, 2025

(54) DIFFUSION BARRIER INCLUDING METAL SILICIDE AND TITANIUM SILICON NITRIDE

(71) Applicant: Eugenus, Inc., San Jose, CA (US)

(72) Inventors: Ajit Dhamdhere, San Jose, CA (US); Sang Hyeob Lee, Fremont, CA (US); Hae Young Kim, San Jose, CA (US)

(21) Appl. No.: 18/954,102

(22) Filed: Nov. 20, 2024

Related U.S. Application Data
(60) Provisional application No. 63/602,309, filed on Nov. 22, 2023.

(51) Int. Cl. H01L 21/768; C23C 16/04; C23C 16/34; C23C 16/42; C23C 16/455; C23C 16/56; H01L 21/3205

(52) U.S. Cl. CPC H01L 21/76841; C23C 16/042; C23C 16/34; C23C 16/42; C23C 16/45531; C23C 16/56; H01L 21/32053

(57) ABSTRACT

The disclosed technology generally relates to forming a diffusion barrier structure, and more particularly to a diffusion barrier comprising a metal silicide and titanium silicon nitride and methods of forming the same. In one aspect, a method of forming a diffusion barrier comprises providing a substrate comprising an exposed silicon surface; forming a metal silicide layer, other than a titanium silicide layer, by exposing the substrate to a metal precursor other than a titanium-containing precursor; and subsequent to forming the metal silicide layer, forming a titanium silicon nitride (TiSiN) layer by cyclically exposing the substrate to a titanium-containing precursor, a nitrogen-containing precursor and a silicon-containing precursor.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

This application claims the priority benefit under 35 U.S.C. § 119(e) to U.S. Provisional Application No. 63/602,309, filed Nov. 22, 2023, entitled “DIFFUSION BARRIER INCLUDING METAL SILICIDE AND TITANIUM SILICON NITRIDE,” the content of which is hereby expressly incorporated by reference in its entirety.

### BACKGROUND

### Field

The disclosed technology generally relates to diffusion barrier structures and more particularly to barrier structures including metal silicide and titanium silicon nitride, and methods of forming the same.

### Description of the Related Art

Thin films based on titanium nitride (TiN) have been widely used in fabrication of various structures in integrated circuits (ICs). For example, TiN has been used in diffusion barriers, various electrodes and metallization structures. Such wide usage of TiN in IC fabrication can be attributed to its structural, thermal and electrical properties. As the dimensions of various IC structures shrink, TiN is formed on features having increasingly smaller dimensions and complex topologies. For example, as the technology node scales to 10 nm node and beyond, there is a need for thin films, e.g., diffusion barriers, that can conformally line high aspect ratio trenches and vias having dimensions as small as few nanometers. While techniques such as physical vapor deposition (PVD) and chemical vapor deposition (CVD) have been used in the IC industry to form TiN diffusion barriers, the increased need for conformality of TiN films to be deposited in smaller trenches or vias may eventually limit their usage. On the other hand, while atomic layer deposition (ALD) has been demonstrated for conformal deposition of TiN films, some electrical properties (e.g., conductivity) and physical properties (e.g., surface roughness) of the film may be inferior compared to TiN films formed using other methods such as physical vapor deposition (PVD). Thus, there is a need for deposition methods for forming TiN-based films with superior properties, including barrier characteristics, surface smoothness and step coverage, relative to TiN films formed by, e.g., PVD and CVD, for use in IC fabrication.

### SUMMARY

In one aspect, a method of forming a diffusion barrier comprises providing a substrate comprising an exposed silicon surface and exposing the substrate to a metal precursor other than a titanium-containing precursor to form a metal silicide layer. The method further comprises, subsequent to exposing the substrate to the metal precursor, cyclically exposing the substrate to a titanium-containing precursor, nitrogen-containing precursor and a silicon-containing precursor to form a titanium silicon nitride layer.

In another aspect, a method of forming a diffusion barrier comprises providing a substrate comprising an exposed silicon surface and converting the exposed silicon surface into a metal silicide layer, other than a titanium silicide layer, in a reactor. The method further comprises, subsequent to converting the exposed silicon surface into the metal silicide layer, forming a titanium silicon nitride layer over the metal silicide layer in situ in the reactor.

In another aspect, a method of forming a diffusion barrier comprises providing a substrate comprising an exposed silicon surface, and exposing the substrate to a metal precursor, other than a titanium-containing precursor, at a temperature sufficient to cause conversion of the exposed silicon surface into a metal silicide layer other than a titanium silicide layer. The method further comprises, subsequent to forming the metal silicide layer, forming a titanium silicon nitride layer directly on the metal silicide layer.

In another aspect, a method of forming a diffusion barrier comprises providing a substrate comprising a silicon region and a dielectric region, selectively forming a metal silicide layer, other than a titanium silicide layer, over the silicon region by exposing an exposed surface of the silicon region to a metal precursor other than a titanium-containing precursor. The method further comprises, subsequent to forming the metal silicide layer, forming a titanium silicon nitride layer on the metal silicide layer.

In another aspect, a method of forming a diffusion barrier comprises providing a substrate comprising an exposed silicon surface and forming a metal silicide layer, other than a titanium silicide layer, by exposing the substrate to a metal precursor other than a titanium-containing precursor. The method further comprises, subsequent to forming the metal silicide layer, forming a titanium silicon nitride layer sequentially exposing the substrate to a titanium-containing precursor, nitrogen-containing precursor, and a silicon-containing precursor.

In yet another aspect, a diffusion barrier structure comprises a substrate comprising a silicon region. The diffusion barrier structure additionally comprises a metal silicide layer other than a titanium silicide on the silicon region. The diffusion barrier further comprises a titanium silicon nitride (TiSiN) layer on the metal silicide layer.

### BRIEF DESCRIPTION OF THE DRAWINGS

FIG. 1 schematically illustrates a cross-sectional view of a diffusion barrier structure comprising thin films comprising tungsten silicide and TiSiN formed on a substrate, according to embodiments.

FIG. 2 schematically illustrates a cross-sectional view of a diffusion barrier structure comprising thin films comprising metal silicide and TiSiN formed on a substrate, according to embodiments.

FIG. 3A schematically illustrates a cross-sectional view of a diffusion barrier structure implemented on a patterned substrate, according to embodiments.

FIG. 3B schematically illustrates a top view of a diffusion barrier structure implemented on a patterned substrate, according to embodiments.

FIG. 4 is a flow chart illustrating a method of forming a barrier structure comprising a metal silicide and TiSiN, according to embodiments.

FIG. 5 is a flow chart illustrating a method of forming a barrier structure comprising a metal silicide and TiSiN, according to embodiments.

FIG. 6 is a flow chart illustrating a method of forming a barrier structure comprising a metal silicide and TiSiN, according to embodiments.

FIG. 7 is a flow chart illustrating a method of forming a barrier structure comprising a metal silicide and TiSiN, according to embodiments.

FIG. 8 is a graph of experimentally measured growth rate of tungsten silicide on a silicon substrate as a function of temperature.

FIG. 9A is a graph of experimentally measured X-ray diffraction spectra of tungsten silicide films formed according to the method according to embodiments.

FIG. 9B is a graph of experimentally measured X-ray diffraction spectra of tungsten silicide films formed according to the method according to embodiments.

FIG. 10 schematically illustrates a barrier structure stack comprising tungsten silicide and TiSiN, according to embodiments.

FIG. 11 is a cross-sectional high-resolution transmission electron microscopy image of a barrier structure stack comprising tungsten silicide and TiSiN, according to embodiments.

FIG. 12 is a cross-sectional high-resolution scanning transmission electron microscopy image of the stack illustrated in FIG. 11.

FIG. 13 is a graph of experimentally measured growth rate of tungsten silicide on different silicon surface orientations.

FIG. 14 is a cross-sectional transmission electron microscopy image of a barrier structure stack comprising tungsten silicide and TiSiN, according to embodiments.

FIG. 15 is a graph illustrating X-ray photoelectron spectra at different depths into a barrier structure stack comprising tungsten silicide and TiSiN, according to embodiments.

FIG. 16 is a flow chart illustrating a vapor deposition cycle for forming a thin film comprising TiSiN, according to some embodiments.

FIG. 17 is a flow chart illustrating a vapor deposition cycle for forming a thin film comprising TiSiN according to an embodiment.

FIG. 18 is a flow chart illustrating a vapor deposition cycle for forming a thin film comprising TiSiN according to an embodiment.

FIG. 19 is a flow chart illustrating a vapor deposition cycle for forming a thin film comprising TiSiN according to an embodiment.

FIG. 20 is a flow chart illustrating a vapor deposition cycle for forming a thin film comprising TiSiN, according to some other embodiments.

### DETAILED DESCRIPTION

Various semiconductor structures incorporate diffusion barriers. For example, interconnect metal deposition including the bit line metal processes employ diffusion barriers to suppress or prevent the diffusion of precursor chemicals (e.g., fluorine, chlorine chemistry) into the layers underneath, and to suppress or prevent the out-diffusion of dopants such as boron and phosphorus from highly-doped Si, poly-Si etc. as well as diffusion/migration of Si. These diffusion barriers should have sufficiently low bulk resistances as well as acceptable contact resistances.

As described above, there is a need in the integrated circuit (IC) industry for conformal thin films, e.g., TiN-based thin films, with superior physical and barrier properties, as well as methods of forming such films. To address these and other needs, disclosed herein is a barrier structure comprising metal silicide thin films and TiSiN thin films, which can be at least partially amorphous, and a cyclic vapor deposition method, which can be an atomic layer deposition (ALD) method, of forming such thin film, which displays the conformality characteristic of a film deposited by ALD, while also having barrier properties that are superior or matching those of TiN films formed by existing physical vapor deposition (PVD) and chemical vapor deposition (CVD) methods. The barrier structure comprising metal silicide thin films and TiSiN thin films can serve as a conformal diffusion barrier. The diffusion barrier can serve multiple functions. One such function of the diffusion barrier is to prevent the diffusion of precursor chemicals, which often contain fluorine or chlorine into the layers underneath the barrier. Another function of the diffusion barrier is to prevent the out-diffusion of dopants such as boron and phosphorous from highly doped silicon or polycrystalline silicon substrate surfaces.

As described above, barrier structures play an important role in integrated circuit (IC) fabrication. While next generation semiconductor devices such as memories including DRAM and NAND are scaling down, there is an increasing motivation for to correspondingly scale down the barrier thickness, e.g., to maintain reasonable aspect ratios of the barrier structures. In addition, such scaling should not substantially compromise various electrical constraints, such as the contact and bulk resistance. As such, there is ever increasing demand for a diffusion barrier with lower contact resistance, as well as lower bulk resistance and improved diffusion barrier properties. The motivation to reduce the resistances is exacerbated by the scaling of contact areas, which are becoming ever smaller with scaling, which in turn is leading to increased contact resistance in devices. For advanced technology nodes, e.g., sub 20 nm nodes, contact resistance is one of the biggest limiting factor to realize high performance integrated circuits. As such, there is a need for forming barrier structures, having low contact and bulk resistances and without significant compromise in electrical and/or physical properties.

To address these and other needs, disclosed herein are diffusion barrier structures and methods of forming the same. The diffusion barrier structure comprises a metal silicide layer other than a titanium silicide layer. The diffusion barrier structure further comprises a titanium silicon nitride layer. The diffusion barrier structure may be formed by providing a substrate comprising an exposed silicon surface and exposing the substrate to a metal precursor other than a titanium-containing precursor to form a metal silicide layer. The method may further comprise, subsequent to exposing the substrate to the metal precursor, sequentially exposing the substrate to a titanium-containing precursor, nitrogen-containing precursor and a silicon-containing precursor to form a titanium silicon nitride layer. The barrier structure comprising a metal silicide layer and a titanium silicon nitride layer deposited according to the methods disclosed herein advantageously has excellent diffusion barrier properties while having lower contact and bulk resistances.

According to various embodiments, the metal silicide and the titanium silicon nitride layers are formed in situ in the same reactor. In some embodiments, the titanium silicon nitride layer may be formed directly on the metal silicide layer. In some embodiments, the metal silicide and the titanium silicon nitride layers may be formed without a change in temperature. Thus, the methods according to embodiments may comprise an integrated metal silicide and titanium silicon nitride deposition process. As a result, the methods according to embodiments may lead to high throughput and productivity.

According to various embodiments, the metal silicide and the titanium silicon nitride layers are formed using thermal processes, without aid of plasma. While plasma-enhanced processes such as plasma enhanced atomic layer deposition (PE-ALD) may be effective in forming conformal films on surfaces having relatively low aspect ratios, such processes may not be effective in in depositing films inside vias and cavities having relative high aspect ratios. Without being limited by theory, one possible reason for this is that a plasma may not reach deeper portions of high aspect ratio vias under some circumstances. It will also be appreciated that plasma may not reach into small openings. In these circumstances, different portions of the vias may be exposed to different amounts of the plasma, leading to undesirable structural effects arising from non-uniform deposition, such as thicker films being deposited near the opening of the via compared to deeper portions (sometimes called cusping or keyhole formation). As such, plasma processes can limit deposition in small openings (e.g., <100 nm) having high aspect ratios (e.g., >2). In contrast, thermal deposition processes described herein provide enhanced step coverage with relatively high bottom surface to sidewall coverage ratios. For these reasons, a thermal cyclic vapor deposition such as thermal ALD may be more advantageous, because such thermal processes do not depend on the ability of the plasma to reach portions of the surface being deposited on.

As described herein, a compound referred to by its constituent elements without specific stoichiometric ratios thereof shall be understood to encompass all possible nonzero concentrations of each element unless explicitly limited. For example, titanium silicon nitride (TiSiN) shall be understood to encompass all possible stoichiometric and nonstoichiometric compositions of titanium silicon nitride that can be expressed by a general formula TiₓSi_{y}N, where x>0 and y>0; tungsten silicide shall be understood to encompass all possible stoichiometric and nonstoichiometric compositions of tungsten silicide that can be expressed by a general formula WSiₓ, where x>0.

The barrier structure comprising metal silicide thin films and TiSiN thin films according to the methods disclosed herein advantageously has excellent diffusion barrier characteristics while having excellent conformality, low surface roughness, decreased thickness, and lower contact and bulk resistivity. These and other characteristics of the thin films can be advantageously tuned by controlling the morphology of the thin films at the nanoscale to have varying degrees of crystallinity and/or homogeneity by tuning the process conditions.

In addition, while some Ti-based barrier structures have been used in the industry, such structures may not be effective in providing effective diffusion barrier properties while still maintaining low contact resistance in advanced (e.g., sub 30 nm) technology nodes. For example, TiN films are polycrystalline can develop a columnar grain morphology, which provides pathways for grain boundary diffusion. Thus, TiN layers may be relatively thick to obtain acceptable diffusion barrier properties. However, because TiN layers have significantly higher resistivity as compared to the contact metal tungsten or copper, thicker layers of TiN occupy more volume, and can result in excessive contact resistance. Furthermore, the surface roughness of the polycrystalline TiN films can be relatively high, contributing further to higher contact resistance. Accordingly, an effective TiN barrier may be too thick for acceptable overall contact or line conductivity, leaving little room for lower resistivity filler materials such as W or Cu. Hence, TiN may not serve as an efficient diffusion barrier for advanced technology nodes.

The inventors have discovered that by forming a diffusion barrier comprising a metal silicide thin film on a silicon substrate, as an intervening layer between a titanium silicon nitride thin film, the barrier structure may have improved bulk and contact resistance properties while maintaining superior diffusion barrier properties. Among other reasons, this may be because, the metal silicide may form a defect-free and sharp interface with a doped polycrystalline silicon substrate, reducing the Schottky barrier and forming an ohmic contact with the silicon substrate. The metal silicide may also exhibit higher thermal stability, preventing degradation of the contact under high-temperature operating conditions.

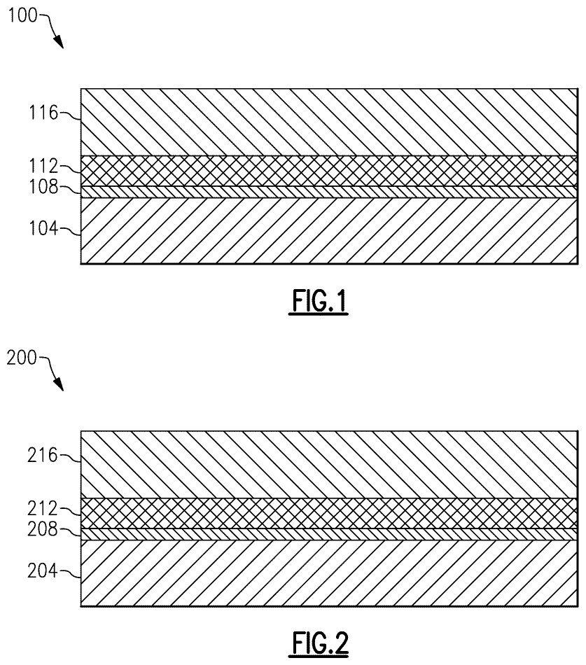

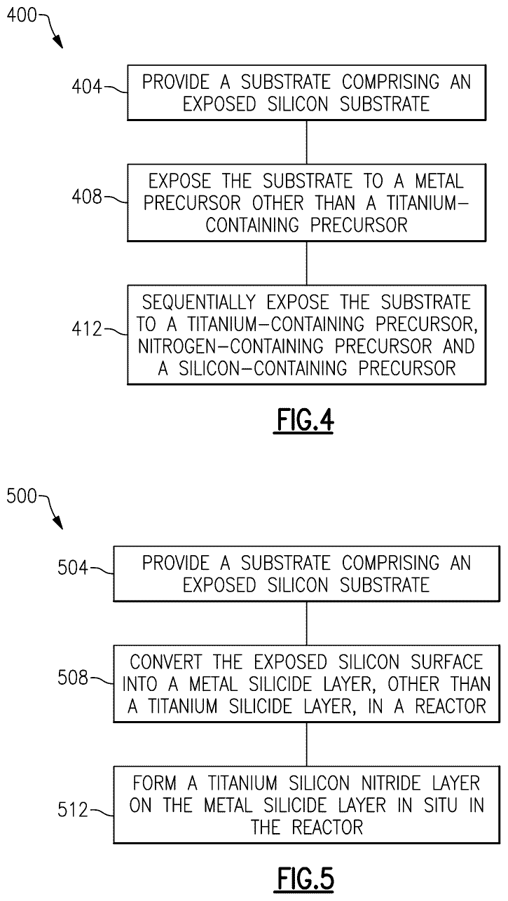

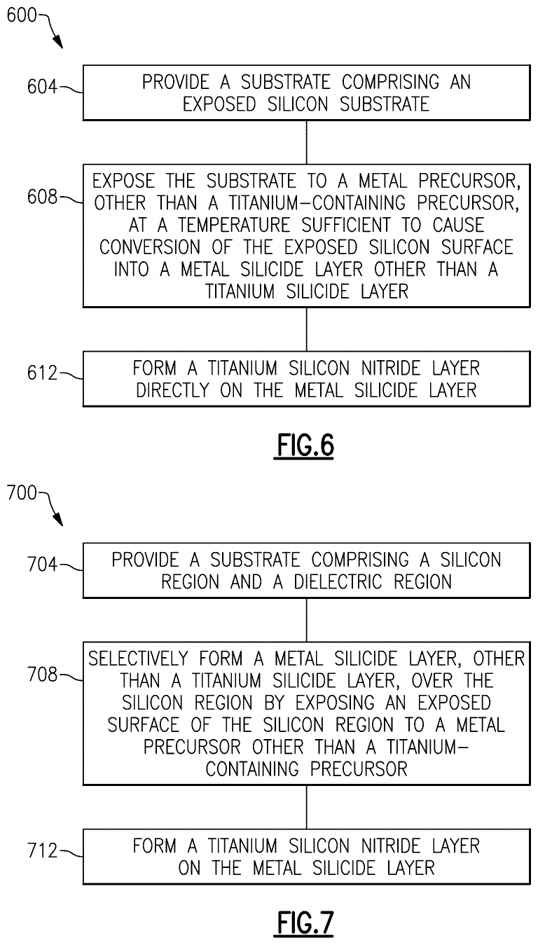

FIG. 1 schematically illustrates a cross-sectional view of a diffusion barrier structure 100 comprising a tungsten silicide layer 108 and a TiSiN layer 112 deposited on a substrate 104, that may be formed using methods according to various embodiments disclosed herein. The barrier structure 100 comprises a substrate 104, e.g., a semiconductor substrate. The substrate 104 may comprise a non-metal surface, e.g., a dielectric and/or a semiconductor surface, on which thin films comprising tungsten silicide or TiSiN may be formed according to methods described herein. The substrate 104 may comprise a single crystalline or polycrystalline silicon having doped regions. The substrate 104 may be doped to ensure that the contact resistance is minimized at the interface with the metal silicide layer 108, allowing for formation of an ohmic contact. The barrier structure 100 disclosed herein can serve as an effective diffusion barrier for dopants such as boron and phosphorous from the doped regions, while still providing low contact resistivity and thickness. The tungsten silicide layer 108 may be formed by chemical vapor deposition (CVD) or a cyclic deposition such as ALD. The tungsten silicide layer 108 may be formed using a tungsten precursor, and in some embodiments, other gases such as H₂ or silicon-containing precursors such as silane (SiH₄) or disilane (SiH₆) may be used. The TiSiN layer 112 may be formed by a cyclic deposition process such as thermal ALD, or with the any of the methods described in reference to FIGS. 4-7. The contact metal 116, such as tungsten, may be formed on the TiSiN layer 112, e.g., using physical vapor deposition (PVD).

The inventors have discovered that the illustrated barrier structure 100 provides improved bulk and contact resistance properties, attributed to the reduction in interface native silicon dioxide, as well as a clean and sharp interface between tungsten silicide layer 108 and silicon of the substrate 104. The interface thus formed between tungsten silicide layer 108 and silicon of the substrate 104 can lead to formation of an ohmic contact. In some embodiments, an electrical resistivity of the diffusion barrier structure 100 may be 5000 μΩ·cm or lower. In some embodiments, an electrical resistivity of the barrier structure may be about the same or lower to an electrical resistivity of a reference TiSiN layer that is formed using the same ALD as that used to form the TiSiN layer 112, but directly formed on a reference silicon substrate surface that is the same as the substrate 104 without a metal silicide layer formed thereon.

As described herein, a bulk resistance refers to a resistance of a material layer to the flow of electrical current through its bulk, or volume, rather than just its surface or interfaces. As described herein, a contact resistance refers to a resistance to the flow of electrical current at the interface between two materials.

FIG. 2 schematically illustrates a cross-sectional view of a diffusion barrier 200 structure comprising a metal silicide layer 208 and a TiSiN layer 212 formed on a substrate 204, according to embodiments. The substrate 204 may have similar properties as the substrate 104 described in reference to FIG. 1. The substrate 204 may be doped specifically to minimize contact resistance with the specific metal used for forming the metal silicide 208. Referring to FIG. 2, the metal silicide layer 208 may be a silicide other than titanium silicide, which may serve as an alternative to tungsten silicide while providing similar contact resistance performance and diffusion barrier properties. The metal silicide layer 208 may be comprised of any suitable metal or metallic material including, for example, metals such as molybdenum (Mo), vanadium (V), hafnium (Hf), niobium (Nb), and zirconium (Zr). The metal silicide layer 208 can provide the same advantages as the tungsten silicide layer 108 described with reference to FIG. 1 to provide improved contact resistance in a barrier structure. The metal silicide layer 208 may be formed by CVD or ALD processes using various metal precursors and other gases such as H₂ and/or silicon-containing precursors such as silane (SiH₄) or disilane (SiH₆). The TiSiN layer 212 may be formed by a cyclic deposition process such as thermal ALD, or with the any of the methods described with respect to FIGS. 4-7. The contact metal 216, such as tungsten, may be formed using physical vapor deposition (PVD).

In some embodiments, an electrical resistivity of the diffusion barrier structure 200 may be lower than 5000μΩ·cm, 4000μΩ·cm, 3000μΩ·cm, 2000μΩ·cm, 1000 μΩ·cm, or lower, or in a range defined by any of these values. In some embodiments, an electrical resistivity of the barrier structure may be about the same or lower to an electrical resistivity of a reference TiSiN layer that is formed using the same ALD as that used to form the TiSiN layer 212, but directly formed on a reference silicon substrate surface that is the same as the substrate 204 without a metal silicide layer formed thereon.

While the barrier structures 100, 200 comprising tungsten silicide, or a metal silicide other than titanium silicide, and TiSiN has been illustrated in FIGS. 1 and 2 as being formed on a planar substrate for clarity, embodiments are not so limited. The benefits of the barrier structure 100, 200 formed using the methods described herein are particularly high when formed on a substrate having topography, e.g., a substrate having aggressively scaled feature sizes or high aspect ratio structures. A high aspect ratio structure may be, e.g., a via, a hole, a trench, a hole, a cavity or a similar structure. This is because, as discussed above, thermal processes described herein provide better step coverage. As described herein, a step coverage may be defined as a ratio between a thickness of a thin film at a lower or bottom region of a high aspect ratio structure and a thickness of the thin film at an upper or top region of the high aspect ratio structure. For example, a surface on which the diffusion barrier is formed may be a silicon region formed in a trench or via formed through a dielectric layer over the substrate. The surface on which the barrier is formed may be a silicon region formed in a via formed through a dielectric layer over the substrate. The silicon regions on which the diffusion barrier structures are formed may be any suitable shape including vias, cavities, holes or trenches.

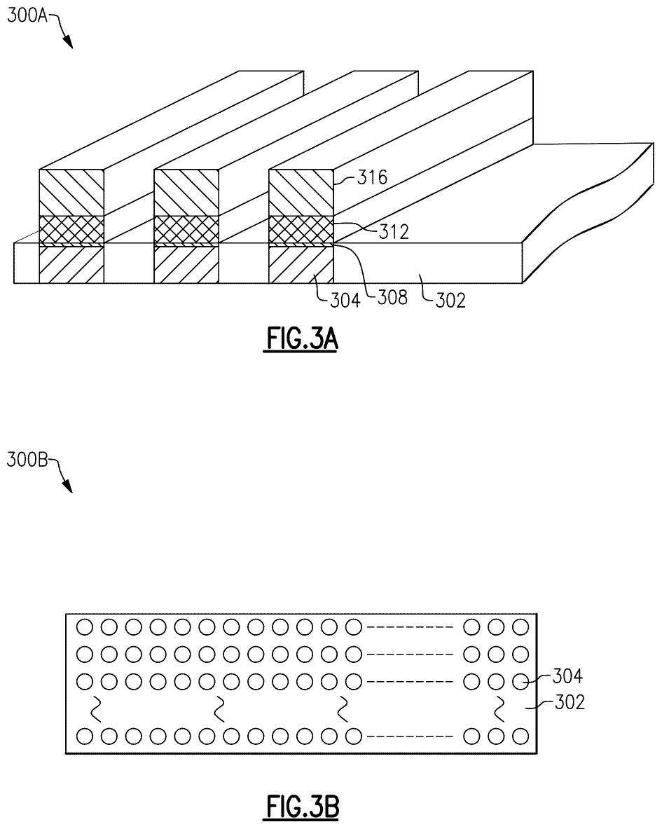

FIG. 3A schematically illustrates a cross-sectional view of an example implementation 300A of diffusion barrier structures according to embodiments. The diffusion barriers may be formed in a trench formed through a dielectric film 302 such as an oxide. At the bottom of the trench, silicon regions 304 may be present. The silicon regions 304 may be doped polysilicon regions. The doping of polysilicon may allow for the silicon to have a much higher reactivity with the metal used for forming the metal silicide. The dopant material and concentration may be chosen based on the metal used for forming the metal silicide. The polysilicon regions may be doped to reduce the Schottky barrier and allow for formation of an Ohmic contact at the between the metal silicide layers 308 and silicon region 304. The metal silicide layer 308 may comprise a metal silicide, e.g., tungsten silicide (WSiₓ). The metal silicide layers 308 may have formed thereon a TiSiN layer 312 and a contact metal 316, such as tungsten.

FIG. 3B schematically illustrates a top-down view of an example semiconductor substrate comprising a silicon region and a dielectric region. The silicon region may comprise doped polysilicon regions 304. The dielectric region may comprise a dielectric film 302 such as an oxide. The dielectric film 302 may comprise silicon dioxide (SiO₂). The polysilicon regions 304 may be via structures, as shown in FIG. 3B. The diffusion barrier and the metal line (e.g., tungsten line) may be formed across a plurality of the via structures. The polysilicon may be heavily doped to promote metal silicide formation. Such structures may be implanted as part of a metal line such as a DRAM or NAND bit line. The selective formation of the metal silicide and TiSiN barrier structure at the contact regions for use in both memory and/or logic devices may allow for low-resistance contacts that ensure fast switching and minimal power loss. However, embodiments are not so limited, and the disclosed barrier structure may be extended to other device types.

Advantageously, the diffusion barrier structures according to embodiments may be formed selectively on the silicon surfaces relative to non-silicon surfaces. Such selective growth of metal silicide thin films and TiSiN thin films on a doped silicon substrate. The diffusion barrier comprising a metal silicide and TiSiN may thus be formed on a variety of topographical structures, including vias, cavities, holes or trenches. The methods described herein may allow for selective growth of a metal silicide layer, such as tungsten silicide, on a semiconductor surface. The selective growth comprises growth of the thin firms of the barrier structure only on the silicon surface, and not a dielectric surface, which may comprise an oxide like SiO₂. Selective growth may be beneficial to prevent the formation of silicides in unwanted regions, such as gate or channel regions of a transistor, where silicide formation may degrade a device. Advantageously, the illustrated barrier structure has a reduced bit line stack height, resulting in a reduced resistive-capacitive delay. This feature is important in high-speed logic and memory devices, where fast switching times are essential for high performance. The selective growth of the barrier structure also advantageously increases the number of contacts per area, improving the contact resistance of the barrier structure.

Without being bound to any theory, selective formation of the metal silicide may occur when, e.g., the exposure time of the underlying silicon region may occur for a duration that is long enough to form a silicide while not long enough to form a metal over non-silicon surfaces such as an oxide surface. Selective formation of the metal silicide may also depend on other factors, including, but not limited to, deposition temperature and pressure, exposure time, annealing temperature, surface condition, metal type, etc. In some embodiments, selective formation of the metal silicide may occur when, e.g., the deposition temperature is high enough to form a metal silicide, while not high enough to form a metal over non-silicon surfaces such as an oxide surface.

FIG. 4 is a flow chart illustrating a method 400 of forming a barrier structure comprising a metal silicide and TiSiN, according to embodiments. The method comprises providing 404 a substrate comprising an exposed silicon surface and exposing 408 the substrate to a metal precursor other than a titanium-containing precursor. Exposing 408 the substrate to a metal precursor other than a titanium-containing precursor may form a metal silicide layer other than a titanium silicide layer. The method 400 further comprises, subsequent to exposing the substrate to the metal precursor, sequentially exposing 412 the substrate to a titanium-containing precursor, nitrogen-containing precursor and a silicon-containing precursor. Sequentially exposing 412 the substrate to a titanium-containing precursor, nitrogen-containing precursor and a silicon-containing precursor may form a titanium silicon nitride layer on the metal silicide layer.

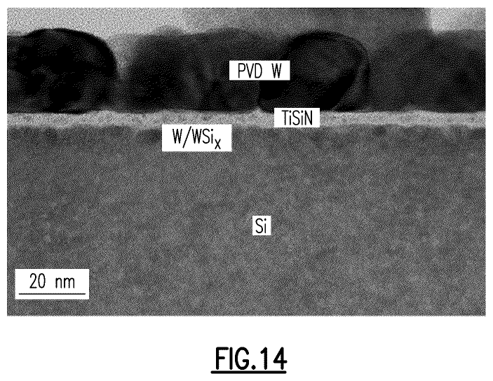

Providing 404 a substrate may comprise providing a substrate comprising exposed monocrystalline or polycrystalline silicon. The substrate may comprise doped silicon. The substrate can be a planar substrate or a substrate comprising a surface topography comprising a plurality of openings, such as trenches or vias, formed on the substrate. The exposed silicon surface of the substrate may have a (001) crystalline orientation. In some embodiments, providing 404 a substrate comprising silicon having a (001) crystalline orientation may lead to a higher level of growth of a metal silicide layer than on a substrate comprising silicon having a different crystalline orientation, e.g., (111), as shown with reference to FIG. 13.

The method 400 comprises exposing 408 the substrate to a metal precursor other than a titanium-containing precursor to form a metal silicide layer. Exposing 408 the substrate to a metal precursor to form the metal silicide layer may be part of a chemical vapor deposition (CVD) or a cyclic deposition process such as atomic layer deposition (ALD). The CVD or ALD processes used for forming the metal silicide layer may be a thermal process without the aid of plasma, or a plasma-enhanced process.

Under a CVD deposition process, a metal precursor other than a titanium-containing precursor may be chosen to form a desired metal silicide. The substrate may then be exposed to the metal precursor gas at a selected process temperature in a reaction chamber, depending on the specific metal being used and the desired properties of the silicide. Once introduced into the chamber, the metal precursor may decompose, and the metal atoms may adsorb onto the heated silicon substrate. The metal atoms may react with the silicon to form the corresponding metal silicide.

In some embodiments, the substrate is also exposed to co-reactant gases such as a silicon-containing precursor, e.g., silane (SiH₄), or disilane (SiH₆), dichlorosilane (SiH₂Cl₂, DCS). In some embodiments, the substrate is also exposed to a reducing agent such as hydrogen gas (H₂). The hydrogen gas may act as a reducing agent to reduce the metal precursor and promote deposition of the metal. The CVD process may produce by-products such as Cl₂ or F₂ gas, in the case of a metal halide precursor. In some embodiments, forming the metal silicide layer may comprise an annealing step to further refine the metal silicide layer after it is deposited. In some embodiments, the process may be performed in a reaction chamber at a temperature higher than 200° C., 300° C., 400° C., 500° C., 600° C., 700° C., 800° C., or a value in a range defined by any of these values. In some embodiments, the process may be performed at a pressure greater than about 1 Torr.

Without limitation, the flow rates of some example gases in a CVD process for forming tungsten silicide (WSiₓ) may be as follows: metal precursor (e.g., WF₆): 0.1-100 sccm, 100-500 sccm, 500-1000 sccm or a value in a range defined by any of these values; H₂: 1000-2000 sccm, 2000-4000 sccm, 4000-6000 sccm, 6000-8000 sccm, 8000-10,000 sccm or a value in a range defined by any of these values; silicon-containing precursor (e.g., SiH₄ or DCS): 100-200 sccm, 200-500 sccm, 500-1000 sccm, 1000-2000 sccm, 2000-5,000 sccm, or a value in a range defined by any of these values.

Under an ALD deposition process, the forming the metal silicide layer may comprise exposing the substrate to one or more cycles, each of the cycles comprising exposing 408 the substrate to a metal precursor other than a titanium-containing precursor. Exposing 408 the substrate to a metal precursor can comprise one or more exposures to the metal precursor. After the one or more exposures to the metal precursor, excess or residual metal precursor or its reaction products that do not remain adsorbed or chemisorbed on the surface of the substrate may be pumped or purged out. It will be appreciated that, in various embodiments, the frequency and the number of repetition of the exposures of the substrate to the metal precursor as well as the number of repetition of cycles as described herein can be varied to obtain a desired thickness and stoichiometry of the resulting metal silicide layer, based on various considerations including susceptibility to stearic hindrance effects of the precursors.

In some embodiments, the substrate may also be exposed to a silicon-containing precursor, such as silane (SiH₄) or disilane (SiH₆) to aid in the formation of the metal silicide layer. In some embodiments, each of the cycles may further comprise one or more exposures to a reducing agent, such as hydrogen (H₂). In some embodiments, forming the metal silicide may further comprise an annealing step. In some embodiments, the process may be performed in a reaction chamber at a temperature higher than 200° C., 300° C., 400° C., 500° C., 600° C., 700° C., 800° C., or a value in a range defined by any of these values. In some embodiments, the process may be performed at a pressure greater than about 1 Torr.

As described herein and throughout the specification, a reactor chamber refers to any reaction chamber including a single wafer processing reaction chamber or a batch wafer processing reaction chamber that is suitably configured for chemical vapor deposition (CVD) or cyclic vapor deposition, which can be atomic layer deposition (ALD), e.g., thermal cyclic vapor deposition or ALD. In a thermal cyclic deposition reactor or an ALD reactor, the substrate may be placed on a suitable substrate such as a susceptor or a carrier boat. The substrate may be directly heated by conduction through a heated susceptor, or indirectly heated by radiation from a radiation source such as a lamp or by convection through a heated chamber wall.

Generally, in a cyclic vapor deposition or ALD process, reactants or precursors, e.g., oxidizing and reducing reactants, are alternatingly introduced into a reaction chamber having disposed therein a substrate. The introduction of one or more reactants or precursors may be in turn be alternated with a purge and/or a pump out process for removing excess reactants or precursors from the reaction chamber. The reactants may be introduced into the reaction chamber under a condition over a suitable period of time such that the surface on which the diffusion barrier is to be deposited is exposed to the reactants, whereby the surface of the substrate can become at least partly saturated with the precursors or reactants and/or a reaction product of the reactants. Excess or residual precursors or reactants may then be purged and/or pumped out of the reaction chamber. A pump out process may be performed by a suitable vacuum pumping process and a purge step may be performed by introducing a non-reactive or an inert gas, e.g., nitrogen or a noble gas, into the reaction chamber. Other techniques also exist for keeping mutually reactive reactants from mixing in the gas phase.

In some embodiments, the exposure to the metal precursor may be performed a plurality of times in sequence. Advantageously, under some circumstances, exposing the substrate to the metal precursor as discussed herein more than once may result in a higher level of surface saturation, e.g., when substantial stearic hindrance effect exists, by exposing more reactive sites for the respective precursor adsorption.

It will be appreciated that, in various embodiments, the number of cycles, the frequency and the number of repetitions of the exposures of the substrate to the metal precursor and/or reducing agent precursors as described herein can be varied to obtain a desired thickness, stoichiometry and other properties described herein in the resulting diffusion barrier layer comprising a metal silicide, based on various considerations including susceptibility to stearic hindrance effects of the precursors.

In some embodiments, the metal precursor may comprise a metal halide precursor. A metal halide precursor may be advantageous for formation of a metal silicide layer because of the highly volatile and reactive nature of the precursor compounds. Metal halide precursors may decompose in controlled conditions to release the metal in a reactive state. For example, the metal halide precursor can decompose under certain thermal or pressure conditions to release metal atoms that may react with the silicon surface to form the metal silicide. Furthermore, metal halide precursors may be easily reducible by reducing agents such as hydrogen or silane. The reduction step may facilitate the formation of metal, which can then react with silicon to form the metal silicide. Furthermore, use of metal halide precursors may allow for precise control over the deposition process of the metal silicide layer, e.g., compositional control, impurity prevention, selective deposition, etc. According to various embodiments, non-limiting examples of the metal halide precursor may be tungsten (VI) fluoride (WF₆), molybdenum (V) chloride (MoCl₅), vanadium (IV) chloride (VCl₄), hafnium (IV) chloride (HfCl₄), niobium (IV) chloride (NbCl₄), or zirconium (IV) chloride (ZrCl₄). The metal that is present in the metal precursor will be present in the resulting metal silicide. Thus, a metal precursor will lead to a formation of the corresponding metal silicide.

Without limitation, metal silicides according to embodiments can be formed by CVD or ALD process using a source gas including a suitable mixture of precursors according to the following reactions:

WF₆ (g)+2Si (s)→WSi₂ (s)+3F₂ (g)

2MoCl₅ (g)+4Si (s)→2MoSi₂ (s)+5Cl₂ (g)

VCl₄ (g)+2Si (s)→VSi₂ (s)+2Cl₂ (g)

HfCl₄ (g)+2Si (s)→HfSi (s)+2Cl₂ (g)

NbCl₄ (g)+2Si (s)→NbSi₂ (s)+2Cl₂ (g)

ZrCl₄ (g)+2Si (s)→ZrSi₂ (s)+2Cl₂ (g)

While the above example reactions imply a direct formation of a metal silicide on a silicon surface from a metal halide, reactions may not be so limited. For example, without being bound to any theory, the reaction may first form an ultrathin, e.g., a sub-monolayer or one or more monolayers of the metal, which subsequently react with silicon of the underlying surface to form a metal silicide. For example, for tungsten, the initial reaction may be described as:

Si (s)+WF₆ (g)→W (s)+SiF₄ (g)↑

Subsequently, W may react with Si to form the WSi₂ according to the above-described reaction. For example, the W may react with Si during a subsequent annealing step.

As described above, the metal silicide layer may be formed using a metal halide precursor such as a metal fluoride precursor or a metal chloride precursor. In some embodiments, additional gases may be present to aid in the formation of the metal silicide. For example, the metal silicide layer may be formed using a metal halide precursor and a silicon-containing precursor. Alternatively, or additionally, the metal silicide layer is formed using a metal halide precursor and hydrogen gas. In some embodiments, the metal silicide layer may be formed using a metal halide precursor, hydrogen gas, and a silicon-containing precursor, e.g., silane (SiH₄) or disilane (Si₂H₆). For tungsten, e.g., the additional gases may aid in the reaction according to:

Si (s)+H₂ (g)+WF₆ (g)→W (s)+SiF₄ (g)↑+HF↑

Si (s)+SiH₄ (g) or DCS (g)+WF₆ (g)→W (s)+SiF₄ (g)↑

For realizing various advantages disclosed herein, e.g., to serve as an effective diffusion barrier with low contact resistance, the resulting example thickness of the metal silicide may be, without limitation, e.g., 1-2 nm, 2-4 nm, 4-6 nm, 6-8 nm, 8-10 nm, 10-12 nm, 12-14 nm, or a value in range defined by any of these values, for instance 3 nm.

Without limitation, the substrate temperature for formation of the metal silicide may be 200-300° C., 300-400° C., 400-500° C. 500-600° C., 600-700° C., 700-800° C. or a temperature in a range defined by any of these values, for instance 650° C. Upper and lower temperature may be determined based on, e.g., reaction kinetics of the underlying silicon and the selectivity of deposition.

Without limitation, the reactor pressure for formation of the metal silicide may be 1-50 Torr, 50-100 Torr, 100-150 Torr, 150-200 Torr, 200-250 Torr, 250-300 Torr, 300-350 Torr, 350-380 Torr or a value in a range defined by any of these values. In some embodiments, the reactor pressure may be greater than 1 Torr.

Still referring to FIG. 4, it will be understood that the method may be carried out over a substrate having been processed through the front-end-of-line, and can include various devices, for instance transistors. Furthermore, the substrate can include one or more of a variety of structures pre-formed thereon, e.g., diffusion regions, isolation regions, electrodes, and metallization structures such as contacts and metallization lines, to name a few, over which the method may be performed. The diffusion barrier comprising a metal silicide and TiSiN may thus be formed on a variety of topographical structures, including vias, cavities, holes or trenches. The surfaces on which the diffusion barrier comprising a metal silicide and TiSiN according to embodiments can be formed include a metallic surface, e.g., a surface of a metallization structure; a semiconductor surface, e.g., a doped or undoped Si surface; and/or a dielectric surface, e.g., an interlayer dielectric (ILD) surface, a mask or a hard mask surface or a gate dielectric surface, to name a few.

In some embodiments, the diffusion barrier comprising a metal silicide and TiSiN may be interposed between a dielectric layer, e.g., an interlayer dielectric and a metallization structure formed by filling a via or a trench and/or between a semiconductor substrate and the metallization structure formed by filling the via or the trench, thereby serving as a diffusion barrier therebetween, among other functionalities, such as an electrical contact. In these embodiments, the dielectric material may be any dielectric material used in integrated circuit fabrication, e.g., silicon oxide, silicon nitride, high K dielectric or low K dielectric, to name a few. The metallization structure can include a metallization line, a contact structure or other conductive structures formed of a metal or a metallic material for electrically connecting the underlying semiconductor material, e.g., a diffusion region, to other parts of an integrated circuit device being fabricated. The metallization structure may be formed of any suitable metal or metallic material including, for example, metals including Al, Cu, Ni, Cr, Co, Ru, Rh, Pd, Ag, Pt, Au, Ir, Ta, and W; conductive metal nitrides including TiN, TaN, WN, and TaCN; conductive metal silicides including tantalum silicides, tungsten silicides, nickel silicides, cobalt silicides and titanium silicides; and conductive metal oxides including RuO₂, to name a few.

Still referring to FIG. 4, the method of forming a diffusion barrier further comprises sequentially exposing 412 the substrate to a titanium-containing precursor, nitrogen-containing precursor, and a silicon-containing precursor. The step of sequentially exposing 412 the substrate to a titanium-containing precursor, nitrogen-containing precursor, and a silicon-containing precursor may form a TiSiN layer or region on the metal silicide layer. In some embodiments, the TiSiN layer or region may be formed directly on the metal silicide layer. In some embodiments, the TiSiN layer or region may be formed in situ in the same reaction chamber as the metal silicide layer. In some embodiments, exposing 412 the substrate to a titanium-containing precursor, nitrogen-containing precursor, and a silicon-containing precursor may comprise one or more vapor deposition cycles, which can be ALD cycles. Each of the one or more vapor deposition cycles may comprise a sequence of alternating and/or non-overlapping exposures to each of the titanium-containing precursor, nitrogen-containing precursor, and the silicon-containing precursor in some specified order. In some embodiments, each of the one or more vapor deposition cycles may comprise one or more deposition phases. Various aspects of depositing a layer or region including TiSiN are disclosed in U.S. Pat. Pub. No. 2022/0301928 and U.S. Pat. Pub. No. 2022/0301929, the contents of which are incorporated herein by reference in their entireties.

As a non-limiting example of a method of depositing TiSiN, each of one or more vapor deposition cycles may comprise exposing the substrate to one or more first vapor deposition phases (“first deposition phases”), wherein at least one of the first deposition phases comprises an exposure to the Ti precursor and an exposure to the N precursor. Each of the one or more vapor deposition cycles may additionally comprise exposing the substrate to one or more second vapor deposition phases (“second deposition phases”), wherein at least one of the second deposition phases comprises an exposure to the Si precursor and may comprise a further exposure to the N precursor. The one or more first deposition phases and the one or more second deposition phases can combine to form one cycle, which in turn can be repeated a plurality of times or cycles. Different cycles can have the same or different number of first and second deposition phases. The combination of exposing the substrate to one or more first deposition phases and exposing to one or more second deposition phases results in a diffusion barrier layer comprising a TiSiN layer or region. Each of exposing the substrate to one or more first deposition phases and exposing the substrate to one or more second deposition phases, in turn, can comprise one or more exposures to respective precursors, such as in pulses, as described below.

For example, exposing the substrate to each of the one or more first deposition phases may comprise subjecting the substrate to one or more exposures to the Ti precursor and one or more exposures to the N precursor. Each exposure to the Ti precursor may be such that the surface of the substrate on which the diffusion barrier is to be deposited is exposed to the Ti precursor, whereby the surface can become substantially or partly saturated with the Ti precursor. After exposing the substrate to the Ti precursor, excess or residual Ti precursor or its reaction products that do not remain adsorbed or chemisorbed on the surface of the substrate may be removed from the substrate surface, such as by having the process chamber pumped or purged out. Similarly, each exposure to the N precursor may be such that the substrate on which the diffusion barrier is to be deposited is exposed to the N precursor, whereby the surface can become substantially or partly saturated with the N precursor. After exposing the substrate to the N precursor, excess or residual N precursor or its reaction products that do not remain adsorbed or chemisorbed or react with the surface of the substrate may be removed from the substrate surface, such as by having the process chamber pumped or purged out. Subjecting the substrate to one or more first deposition phases each comprising one or more exposures to the Ti precursor and one or more exposures to the N precursor may locally form one or more monolayers or a region formed substantially of TiN as-deposited.

In some embodiments, the exposure to the Ti precursor in a given first deposition phase may be performed a plurality of times in sequence. Similarly, the exposure to the N precursor in a given first deposition phase may be performed a plurality of times in sequence. Advantageously, under some circumstances, exposing the substrate to the Ti and/or N precursors more than once may result in a higher level of surface saturation, e.g., when substantial stearic hindrance effect exists, by exposing more reactive sites for the respective precursor adsorption or reaction.

In various embodiments, exposing the substrate to each of the one or more second deposition phases may comprise subjecting the substrate to one or more exposures to the Si precursor. Each exposure to the Si precursor may be such that the surface of the substrate on which the diffusion barrier is to be deposited is exposed to the Si precursor, whereby the surface can become substantially or partly saturated with the Si precursor. After exposing the substrate to the Si precursor, excess or residual Si precursor or its reaction products that do not remain adsorbed or chemisorbed on the surface of the substrate may be removed from the substrate surface, such as by having the process chamber pumped or purged out. Subjecting the substrate to one or more second deposition phases each comprising one or more exposures to the Si precursor may locally form one or more monolayers or a region formed substantially of Si, as-deposited.

In some embodiments, the exposure to the Si precursor in a given second deposition phase may be performed a plurality of times in sequence. Advantageously, under some circumstances, exposing the substrate to the Si precursor more than once may result in a higher level of surface saturation, e.g., when substantial stearic hindrance effect exists, by exposing more reactive sites for the respective precursor adsorption or reaction.

In some embodiments, exposing to the substrate to each of the one or more second deposition phases comprises subjecting the substrate to one or more exposures to the Si precursor and further subjecting the substrate to one or more exposures to a N precursor, which can be the same as or different from the N precursor of the first deposition phases. Each exposure to the Si precursor is such that the surface of the substrate on which the diffusion barrier is to be deposited is exposed to the Si precursor, whereby the surface can become substantially or partly saturated with the Si precursor. After exposing the substrate to the Si precursor, excess or residual Si precursor or its reaction products that do not remain adsorbed or chemisorbed on the surface of the substrate may be removed from the substrate surface, such as by having the process chamber pumped or purged out. Each exposure to the N precursor may be such that the surface of the substrate on which the diffusion barrier is to be deposited is exposed to the N precursor, whereby the surface can become substantially or partly saturated with the N precursor. After the one or more further exposures to the N precursor, excess or residual N precursor or its reaction products that do not react with the surface of the substrate may be removed from the substrate surface, such as by having the process chamber pumped or purged out. Subjecting the substrate to one or more second deposition phases each comprising one or more exposures to the Si precursor and one or more exposures to the N precursor may locally form one or more monolayers or a region formed substantially of SiN, as-deposited.

In some embodiments, the exposure to the Si precursor in a given second deposition phase may be performed a plurality of times in sequence. Similarly, the further exposure to the N precursor may be performed a plurality of times in sequence. Advantageously, under some circumstances, exposing the substrate to the Si and/or N precursors as discussed herein more than once may result in a higher level of surface saturation, e.g., when substantial stearic hindrance effect exists, by exposing more reactive sites for the respective precursor adsorption.

It will be appreciated that, in various embodiments, number of cycles each including one or both of the first and second deposition phases, the frequency and number of repetition of the first deposition phases and the frequency and number of repetition of the second deposition phases, the frequency and the number of repetitions of the exposures of the substrate to the Ti precursor and the N precursor during the first deposition phases, and the frequency and the number of repetitions of the exposures of the substrate to the Si precursor or the Si precursor and the N precursor during the second deposition phases as described herein can be varied to obtain a desired thickness, stoichiometry and other properties described herein in the resulting diffusion barrier layer comprising TiSiN, based on various considerations including susceptibility to stearic hindrance effects of the precursors.

Depending on the circumstances or a film characteristic being sought, it may be advantageous to initiate the deposition of the diffusion barrier comprising TiSiN with one or the other of the exposures of the substrate to a first deposition phase or a second deposition phase. For example, the inventors have found that, exposing the substrate to one or more second deposition phases (Si precursor and/or N precursor) first, followed by exposing the substrate to one or more first deposition phases (Ti precursor and/or N precursor), may be particularly advantageous in enhancing layer-by-layer growth mode of the diffusion barrier layer, thereby increasing conformality and reducing surface roughness, e.g., when the substrate surface comprises a nonmetallic surface, e.g., an insulating surface such as the sidewalls of a trench or a via formed in an interlayer dielectric (ILD) layer, or a semiconductor surface such as a Si diffusion region.

However, embodiments are not so limited and in other embodiments, it may be more advantageous to expose the substrate to one or more first deposition phases (Ti precursor or N precursor) first, followed by exposing the substrate to one or more second deposition phases (Si precursor or N precursor), e.g., for reducing contact resistance while maintaining good conformality and surface roughness, e.g., when the substrate surface comprises a metallic surface (e.g., a W, Al, or Cu metal metallization).

Under some circumstances, the sequence of first and second deposition phases may result in a thin film having regions or layers that are detectably rich in TiN and Si or SiN, depending on the sequence as described above. However, under other circumstances, despite the distinct sequence of exposures to first and second deposition phases, the resulting thin film may be substantially homogenous TiSiN thin films, as described in further infra.

According to various embodiments, non-limiting examples of the Ti precursor for forming the thin film, e.g., diffusion barrier layer or region, include titanium tetrachloride (TiCl₄), tetrakis(dimethylamino)titanium (TDMAT) or tetrakis(diethylamino)titanium (TDEAT).

According to various embodiments, non-limiting examples of the N precursor for forming the thin film, e.g., diffusion barrier layer or region, include ammonia (NH₃), hydrazine (N₂H₄) or monomethylhydrazine (CH₃(NH)NH₂, “MMH”). As noted above, different N precursors can be employed for the first and second deposition phases, and indeed different precursors can be used for different cycles of the same phase.

According to various embodiments, non-limiting examples of the inert gas for purging include nitrogen N₂ or a noble gas such as Ar.

According to some embodiments, the Si precursor for forming the diffusion barrier layer may be a hydride precursor. Examples of the hydride precursor include silane (SiH₄) and disilane (Si₂H₆). According to some other embodiments, the Si precursor for forming the diffusion barrier layer may be a chlorine-containing precursor, such as a silicon chloride or a chlorosilane. Examples include silicon tetrachloride (SiCl₄), monochlorosilane (SiH₃Cl, “MCS”), dichlorosilane (SiH₂Cl₂, “DCS”), trichlorosilane (SiHCl₃), hexachlorodisilane (Si₂Cl₆, “HCDS”) and octachlorotrislane (Si₃Cl₈, “OCTS”). The inventors have found that the diffusion barrier layer comprising TiSiN may be desirably formed using a silicon and chlorine-containing Si precursor when a higher level of saturation of the surface by the precursor is desired under a wide variety of conditions due to reduced steric hindrance relative to organic silicon precursors.

For realizing various advantages disclosed herein, e.g., to serve as an effective diffusion barrier, the layer comprising TiSiN can have a thickness that does not exceed about 10 nm, 7 nm, 4 nm, 2 nm, 1 nm or has a value in a range defined by any of these values or outside of these values, according to embodiments. For example, the TiSiN layer may have a thickness of about 2 nm. These thickness can be substantially lower compared to TiN barriers having similar effectiveness as a diffusion barrier.

For realizing various advantages disclosed herein, e.g., to serve as a diffusion barrier, the thin film comprising TiSiN may be formed at a substrate temperature of 250-300° C., 300-400° C., 350-400° C., 400-450° C., 450-500° C., 500-550° C. 550-600° C., 600-650° C., or a temperature in a range defined by any of these values, for instance about 400° C., according to embodiments.

For realizing various advantages disclosed herein, e.g., to serve as an effective diffusion barrier, the exposure times or pulse durations of the various precursors are in the range of about 0.1-5 sec., 5-10 sec., 10-20 sec., 20-30 sec, 30-40 sec, 40-50 sec., 50-60 sec., or a duration in a range defined by any of these values or higher, according to embodiments.

In summary, forming a TiSiN layer may comprise exposing a substrate to one or more cycles each including one or more first deposition phases and/or one or more second deposition phases. Each of the first deposition phases in turn comprises one or more exposures to a Ti precursor alternating with one or more exposures to a N precursor. According to some embodiments, each of the second deposition phases in turn comprises one or more exposures to a Si precursor. According to some other embodiments, each of the second deposition phases comprises one or more exposures to a Si precursor alternating with one or more exposures to a N precursor. The resulting diffusion barrier layer comprises a TiSiN layer or region. According to various embodiments, the frequency and the number of exposures of the substrate to each of the Ti precursor, the N precursor and the Si precursor, and the frequency and the number of exposures of the substrate to each of the cycles, first deposition phases and second deposition phases, as well as the order of the exposures, may be tailored to obtain a desired stoichiometry, thickness and degree of crystallinity, as described herein. The diffusion barrier structure comprising the TiSiN layer may undergo an annealing step after the TiSiN layer is deposited.

FIG. 5 is a flow chart illustrating a method 500 of forming a barrier structure comprising a metal silicide and TiSiN, according to embodiments. The method comprises providing 504 a substrate comprising an exposed silicon surface. The substrate may possess similar properties as the substrate discussed with respect to FIG. 4. The method additionally comprises converting 508 the exposed silicon surface into a metal silicide layer, other than a titanium silicide layer, in a reactor. The method further comprises, subsequent to converting the exposed silicon surface into the metal silicide layer, forming 512 a titanium silicon nitride layer over the metal silicide layer in situ in the reactor.

Converting 508 the exposed silicon surface to a metal silicide may be performed using CVD or ALD, as described above with respect to FIG. 4. In some embodiments, converting 508 the exposed silicon surface to a metal silicide layer may be achieved by PVD or other known deposition processes. Converting 508 the exposed silicon surface to a metal silicide may comprise an annealing step, e.g., rapid thermal annealing (RTA). The rapid heating may cause an overlying metal layer to react with the silicon and form a metal silicide layer. The conversion of the silicon surface to the metal silicide layer may occur in a reaction chamber suitable for the specific process used for the conversion. For example, when converting 508 the exposed silicon surface to a metal silicide is achieved using ALD, the reaction chamber may be capable of pumping and purging out precursors or reactants.

The method 500 comprises forming 512 a titanium silicon nitride (TiSiN) layer over the metal silicide layer in situ in the same reactor as converting 508 the exposed silicon surface to the metal silicide layer. Forming 512 the TiSiN layer in situ with the metal silicide layer may have several benefits, including but not limited to, lower risk of contamination, higher throughput, and allowing for a robust, repeatable process. Forming 512 the TiSiN layer may comprise a cyclic deposition process such as ALD, which comprises exposing the substrate to a titanium-containing precursor, a nitrogen-containing precursor, and a silicon-containing precursor, as described with respect to FIG. 4. The substrate may undergo rapid thermal annealing (RTA), e.g., at 1050° C. for sixty seconds, as part of forming 512 the titanium silicon nitride layer over the metal silicide layer. The resulting deposited TiSiN film on the metal silicide may show conformal defect free deposition. Furthermore, no interdiffusion of the metal silicide and the TiSiN may be present after the RTA step, as shown with respect to FIG. 14.

FIG. 6 is a flow chart illustrating a method 600 of forming a barrier structure comprising a metal silicide and TiSiN, according to embodiments. The method of forming a diffusion barrier comprises providing 604 a substrate comprising an exposed silicon surface. The substrate may possess similar properties as the substrate discussed with respect to FIG. 4, and exposing 608 the substrate to a metal precursor, other than a titanium-containing precursor, at a temperature sufficient to cause conversion of the exposed silicon surface into a metal silicide layer other than a titanium silicide layer.

Exposing 608 the substrate to a metal precursor, other than a titanium-containing precursor, at a temperature sufficient to cause conversion of the exposed silicon surface into a metal silicide layer other than a titanium silicide (TiSiₓ) layer may result in a more thermally stable metal silicide layer than TiSiₓ. For example, tungsten silicide (WSiₓ) has been shown to have superior thermal stability to TiSiₓ and have a much higher melting point. The thermal stability of the metal silicide layer other than titanium silicide may allow for less agglomeration of the silicide phase than TiSiₓ. The agglomeration of the silicide phase may result in higher resistivity, reduced film uniformity, and degraded barrier properties. Thus, these effects may be avoided by forming a metal silicide layer that is more thermally stable than TiSiₓ. The temperature sufficient to cause conversion of the exposed silicon surface into a metal silicide layer other than a TiSiₓ layer may be 200-300° C., 300-400° C., 400-500° C. 500-600° C., 600-700° C., 700-800° C. or a temperature in a range defined by any of these values, for instance 650° C.

The method 600 further comprises, subsequent to forming the metal silicide layer, forming 612 a titanium silicon nitride layer directly on the metal silicide layer. Forming 612 the TiSiN layer may comprise a cyclic deposition process such as ALD, which comprises exposing the substrate comprising an exposed metal silicide surface to a titanium-containing precursor, a nitrogen-containing precursor, and a silicon-containing precursor, as described with respect to FIG. 4. The substrate may undergo rapid thermal annealing (RTA), e.g., at 1050° C. for sixty seconds, as part of forming 612 the titanium silicon nitride layer directly on the metal silicide layer. The resulting deposited TiSiN film on the metal silicide may show conformal defect free deposition. Furthermore, no interdiffusion of the metal silicide and the TiSiN may be present after the RTA step, as shown with respect to FIG. 14.

FIG. 7 is a flow chart illustrating a method 700 of forming a barrier structure comprising a metal silicide and TiSiN, according to embodiments. The method 700 of forming a diffusion barrier comprises providing 704 a substrate comprising a silicon region and a dielectric region. The dielectric region may comprise a dielectric film such as an oxide, e.g., silicon dioxide. The silicon region may comprise a plurality of via structures, as shown in FIG. 3B, comprising doped silicon surfaces. The silicon may be heavily doped to promote selective formation of the metal silicide layer on the silicon region and preventing unwanted formation of metal or metal silicide on the dielectric region.

The method 700 further comprises selectively forming 708 a metal silicide layer, other than a titanium silicide layer, over the silicon region by exposing an exposed surface of the silicon region to a metal precursor other than a titanium-containing precursor. Selectively forming 708 the metal silicide layer, other than a titanium silicide layer, may be performed using CVD or ALD, as described above with respect to FIG. 4. In some embodiments, selectively forming 708 the metal silicide layer may be achieved by PVD or other known deposition processes. The benefits of selective formation of the metal silicide layer are discussed with respect to FIG. 3B.

The method further comprises forming 712 a titanium silicon nitride layer on the metal silicide layer. Forming 712 the TiSiN layer may comprise a cyclic deposition process such as ALD, which comprises exposing the substrate to a titanium-containing precursor, a nitrogen-containing precursor, and a silicon-containing precursor, as described with respect to FIG. 4. The substrate may undergo rapid thermal annealing (RTA), e.g., at 1050° C. for sixty seconds, as part of forming 712 the titanium silicon nitride layer on the metal silicide layer. The resulting deposited TiSiN film on the metal silicide may show conformal defect free deposition. Furthermore, no interdiffusion of the metal silicide and the TiSiN may be present after the RTA step, as shown with respect to FIG. 14.

Various experimental structures of TiSiN films were deposited in situ on top of a metal silicide layer, e.g., WSiₓ thin films, in order to integrate and characterize the Ohmic contact between WSiₓ and TiSiN. Different TiSi_{y}N films with varying x were deposited on ohmic WSiₓ/Si. The nonuniformity was improved to ˜4% by varying above mentioned parameters. These films were characterized by various characterization techniques: ellipsometry for thickness measurement, XRR for thickness, XRD for phase identification, HRTEM and HRSTEM for Si/WSiₓ and WSiₓ/TSN interfaces, defects like work holes, and to examine the integrity stack, XPS was used for determining elemental distribution and chemical bonding information.

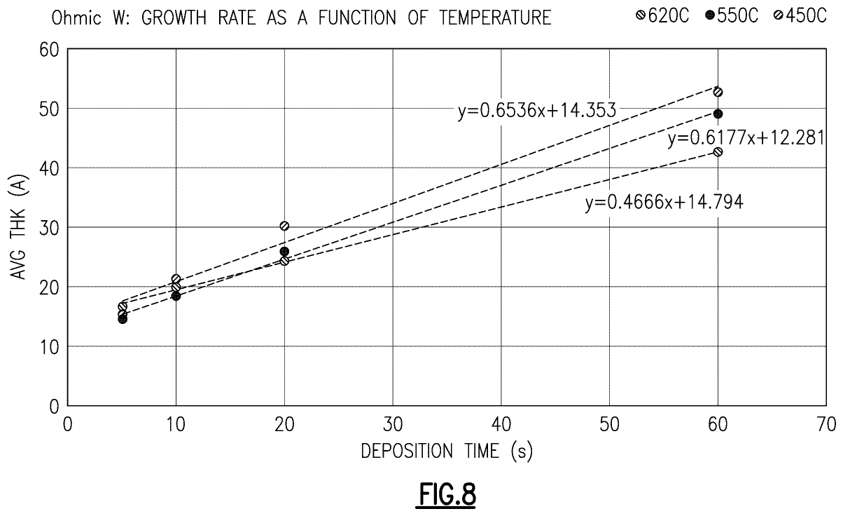

FIG. 8 is a graph of experimentally measured growth rate of tungsten silicide on a silicon substrate as a function of temperature. As illustrated, increasing temperatures of the process were observed to result in a reduced growth rate of the tungsten silicide films.

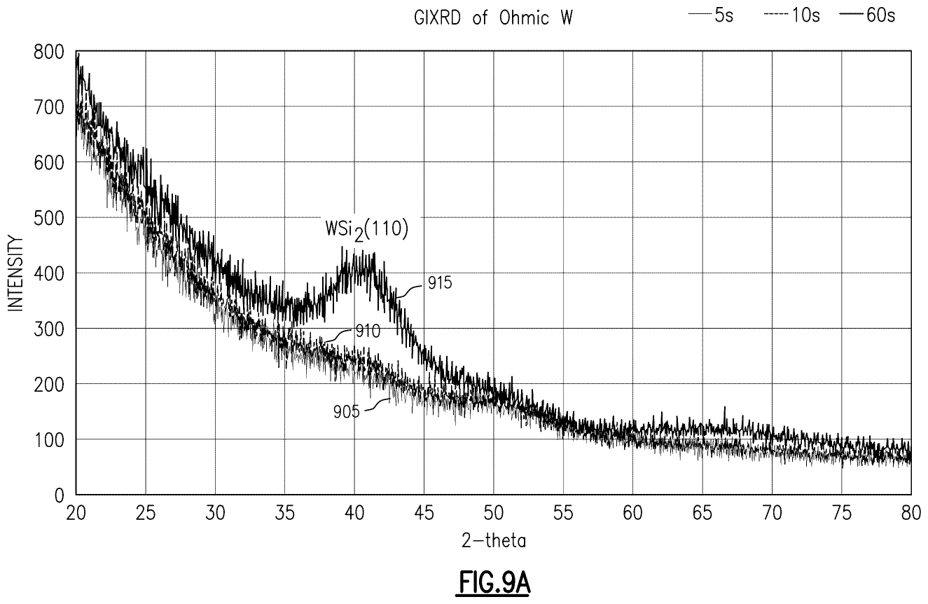

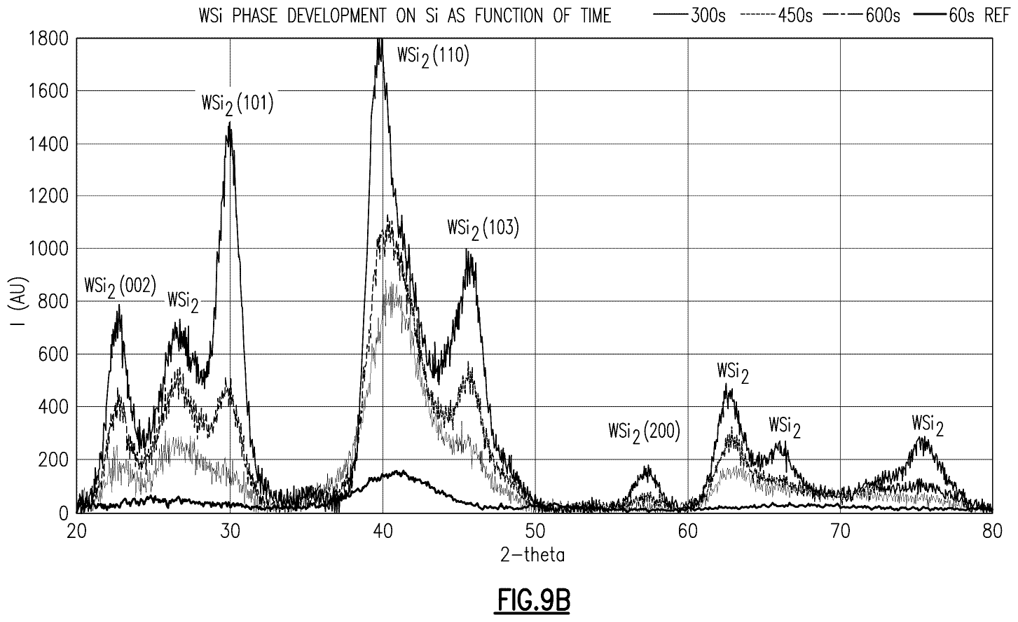

FIG. 9A is a graph of experimentally measured X-ray diffraction spectra of tungsten silicide ultrathin films deposited according to the method illustrated in FIG. 4A. The line 905 shows the measured X-ray diffraction spectra for a deposition time of 5 seconds, the line 910 shows the measure X-ray diffraction spectra for a deposition time of 10 seconds, and the line 915 shows the X-ray diffraction spectra for a deposition time of 60 seconds. The peak on in the line 915 on the graph confirms that a tungsten silicide thin film was formed on the substrate by 60 seconds.

FIG. 9B is a graph of experimentally measured X-ray diffraction spectra of tungsten silicide ultrathin films showing phase evolution as a function of duration. The peaks for each of the lines on the graph show how the phase of tungsten silicide changes over time, and therefore thickness, of the tungsten silicide layer.

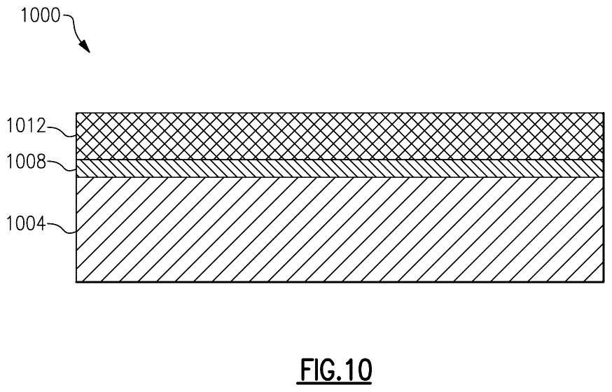

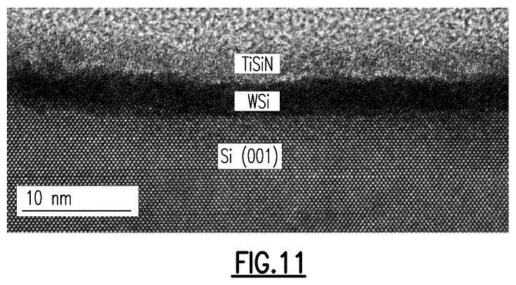

FIG. 10 schematically illustrates the barrier structure stack 1000 comprising a silicon substrate 1004, a metal silicide layer 1008, and a TiSiN layer 1012, according to embodiments. The silicon substrate may be doped and have a (001) crystal orientation to promote growth of the metal silicide layer 1008. The metal silicide layer 1008 may comprise a metal silicide other than titanium silicide and forming an ohmic contact with the doped silicon. Finally, the TiSiN layer 1012 may be deposited on the metal silicide layer 1008 to form the disclosed diffusion barrier structure having improved contact resistance.

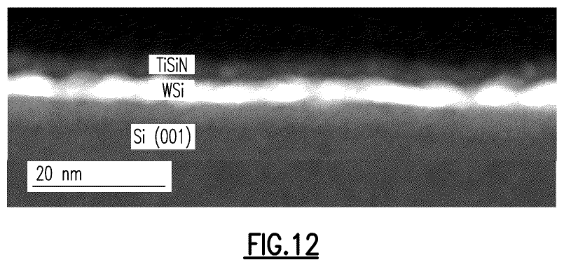

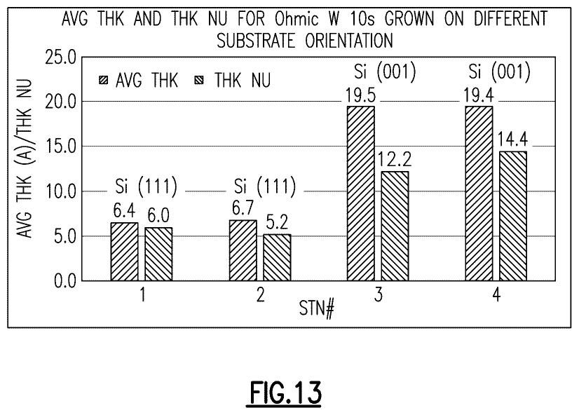

FIGS. 11 and 12 show cross-sectional high-resolution transmission electron microscopy (HREM) and high-resolution scanning transmission electron microscopy (HRSTEM) images of the stack schematically illustrated in FIG. 7. The images show that the interface of the tungsten silicide is defect free and sharp, allowing for lower contact resistance. The image also shows that the TiSiN thin films deposited on tungsten silicide according to the methods described herein, show a conformal, defect-free deposition.

FIG. 13 is a graph of experimentally measured growth rate of tungsten silicide on different silicon substrate orientations. The graph shows that tungsten silicide exhibits a higher growth rate on silicon (001) substrates, rather than silicon (111) substrates.

FIG. 14 is a cross-sectional bright field transmission electron microscopy image of the stack schematically illustrated in FIG. 7, further comprising a tungsten contact layer. The image shows that the tungsten silicide and TiSiN thin films show no interdiffusion after undergoing rapid thermal annealing at 1050° C. for sixty seconds. It will be appreciated that the tungsten silicide layer shows much higher thermal stability than a titanium silicide layer, as it has a much higher melting point. Thus, advantageously, the diffusion barrier will show less agglomeration of the silicide phase after rapid thermal annealing.

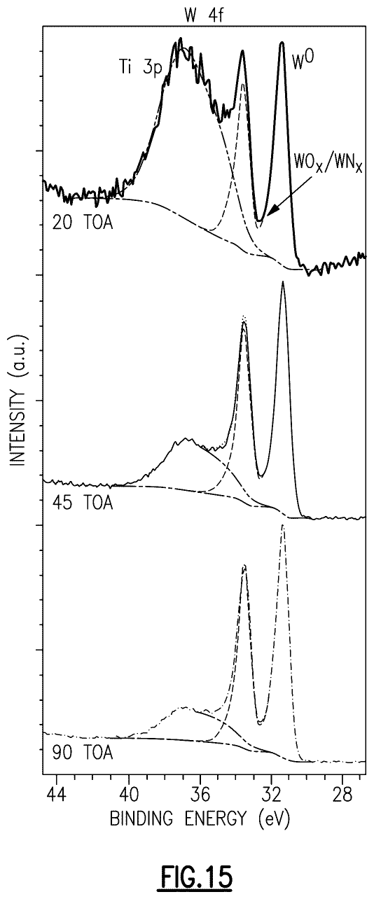

FIG. 15 illustrates X-ray photoelectron spectra illustrating binding energy of tungsten 4f electron at different depths from the surface (2 nm, 4.5 nm, 9 nm) into a diffusion barrier stack including tungsten silicide and TiSiN layers formed, according to embodiments. The graph shows that a tungsten silicide layer, according to embodiments, is formed with high quality and negligible presence of tungsten oxide (WOₓ) and tungsten nitride (WNₓ) phases. The use of silicon-containing precursors, e.g., silane or disilane, or a reducing agent such as H₂ may be useful in preventing the formation of unwanted WOₓ and WNₓ, while promoting the formation of W⁰/WSiₓ.

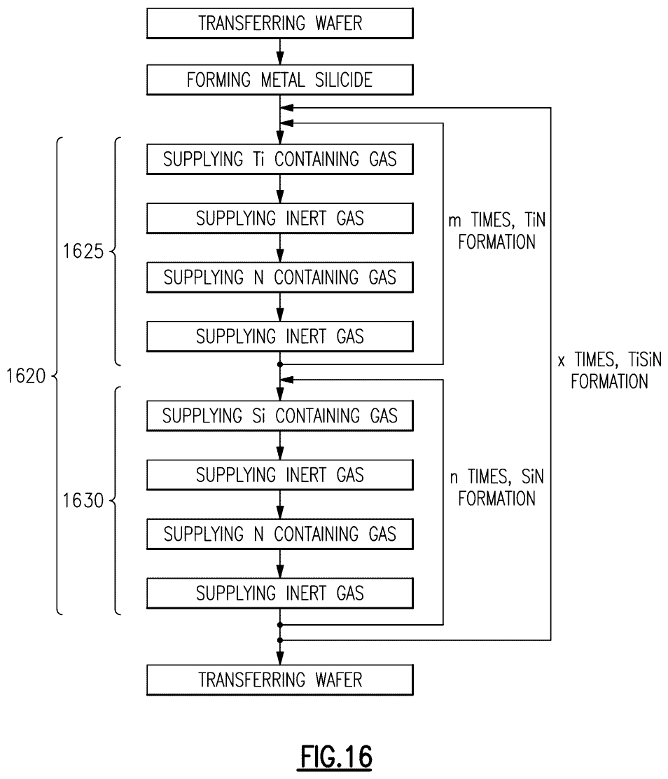

FIG. 16 is a flow chart illustrating a method of forming the TiSiN layer, according to some embodiments. The illustrated method of depositing the TiSiN layer includes exposing 1620 the semiconductor substrate to one or more vapor deposition cycles, which can be ALD cycles, comprising exposing 1625 the semiconductor substrate to one or more (m) first deposition phases and exposing 1630 the semiconductor substrate to one or more (n) second deposition phases. Each of the first deposition phases in turn comprises a plurality of alternating exposures to a Ti precursor and a N precursor, and each of the second deposition phases in turn comprises a plurality of alternating exposures to a Si precursor and a N precursor.

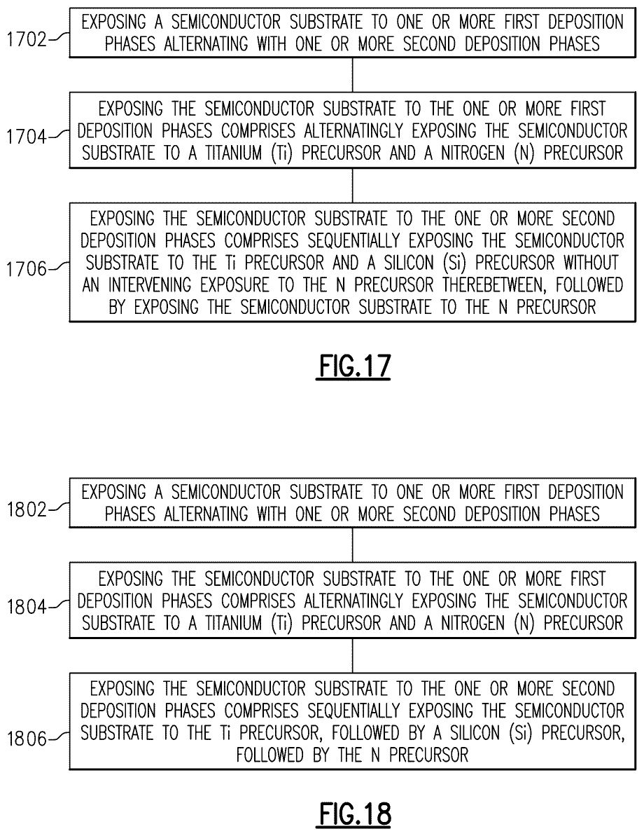

FIGS. 17-19 illustrate alternative or further improved methods of forming a diffusion barrier comprising TiSiN with further improvement in roughness and continuity at ultralow thicknesses, as well as higher precision in controlling the Ti content, such that the resistivity can be lowered with less variability.

FIG. 17 is a flow chart illustrating a method of forming a diffusion barrier comprising TiSiN, according to an embodiment. The method includes a step 1702 of exposing a semiconductor substrate to one or more first deposition phases alternating with one or more second deposition phases. In the method, exposing 1704 the semiconductor substrate to the one or more first deposition phases comprises alternatingly exposing the semiconductor substrate to a titanium (Ti) precursor and a nitrogen (N) precursor. In the method, exposing 1706 the semiconductor substrate to the one or more second deposition phases comprises sequentially exposing the semiconductor substrate to the Ti precursor and a silicon (Si) precursor without an intervening exposure to the N precursor therebetween, followed by exposing the semiconductor substrate to the N precursor.

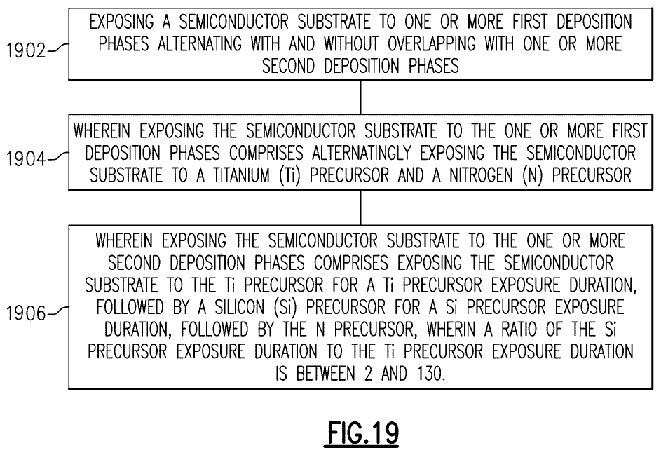

FIG. 18 is a flow chart illustrating a method of forming a diffusion barrier comprising TiSiN, according to another embodiment. The method includes a step of exposing 1802 a semiconductor substrate to one or more first deposition phases alternating with one or more second deposition phases. In the method, exposing 1804 the semiconductor substrate to the one or more first deposition phases comprises alternatingly exposing the semiconductor substrate to a titanium (Ti) precursor and a nitrogen (N) precursor. In the method, exposing 1806 the semiconductor substrate to the one or more second deposition phases comprises sequentially exposing the semiconductor substrate to the Ti precursor, followed by a silicon (Si) precursor, followed by the N precursor.

FIG. 19 is a flow chart illustrating a method of forming a diffusion barrier comprising TiSiN according to another embodiment. The method includes a step of exposing 1902 a semiconductor substrate to one or more first deposition phases alternating with one or more second deposition phases. In the method, exposing 1904 the semiconductor substrate to the one or more first deposition phases comprises alternatingly exposing the semiconductor substrate to a titanium (Ti) precursor and a nitrogen (N) precursor. In the method, exposing 1906 the semiconductor substrate to the one or more second deposition phases comprises exposing the semiconductor substrate to the Ti precursor for a Ti precursor exposure duration, followed by a silicon (Si) precursor for a Si precursor exposure duration, followed by the N precursor, wherein a ratio of the Si precursor exposure duration to the Ti precursor exposure duration is between 2 and 130.

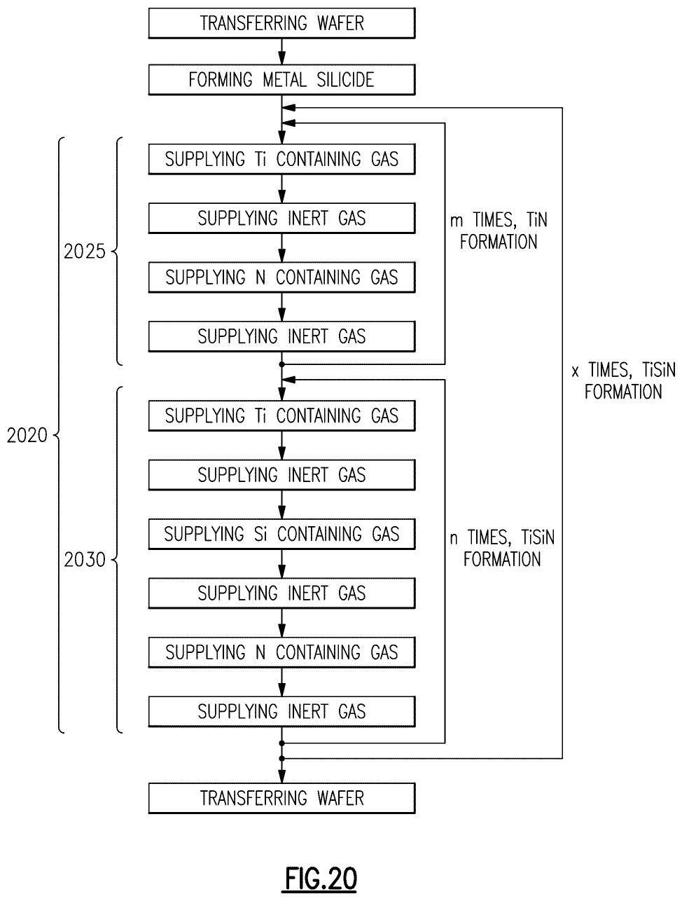

FIG. 20 is a flow chart illustrating a method for forming a thin film comprising TiSiN, according to embodiments illustrating a sequence of precursor exposures compatible with any of the embodiments illustrated above with respect to FIGS. 17-19 in which, unlike the method described above with respect to FIG. 16, in the second deposition phase, a Ti precursor precedes a Si precursor exposure that is followed by a N precursor exposure. The illustrated method includes exposing 2020 a substrate to one or more (x) vapor deposition cycles each including exposing 2025 the semiconductor substrate to one or more (m) first deposition phases and exposing 2030 the semiconductor substrate to one or more (n) second deposition phases. The first and second deposition phases alternate with each other without temporally overlapping in the illustrated embodiment. In the illustrated method, the order of exposing 2025 the semiconductor substrate to one or more first deposition phases may be substantially the same as exposing 1625 the semiconductor substrate to one or more (m) first deposition phases described above with respect to FIG. 16. In particular, exposing 2025 the semiconductor substrate to one or more first deposition phases comprises alternatingly exposing the semiconductor substrate to a titanium (Ti) precursor and a nitrogen (N) precursor, in a similar manner as described above with respect to FIG. 16, the details of which are not repeated herein for brevity.

However, unlike the method described above with respect to FIG. 16, in the method illustrated in FIG. 20, exposing the semiconductor substrate to each of the second deposition phases additionally comprises exposing the substrate to a titanium (Ti) precursor. In particular, exposing 2030 the semiconductor substrate to one or more second deposition phases comprises sequentially exposing the semiconductor substrate to the Ti precursor, followed by a silicon (Si) precursor, followed by the N precursor.

Additionally or alternatively, exposing 2030 the semiconductor substrate comprises sequentially exposing the semiconductor substrate to the Ti precursor and a Si precursor without an intervening exposure to the N precursor, followed by exposing the semiconductor substrate to the N precursor. In the illustrated embodiment of FIG. 20, when a second deposition phase immediately follows a first deposition phase, exposing 2025 the semiconductor substrate to the first deposition phase comprises exposing the semiconductor substrate to the N precursor as a last precursor, and exposing the semiconductor substrate to the Ti precursor as a first precursor of the second deposition phase.

Below are additional examples of methods for forming a diffusion barrier comprising a metal silicide layer and a TiSiN layer, as described herein.

### Additional Examples

1. A method of forming a diffusion barrier, the method comprising:
providing a substrate comprising an exposed silicon surface;
exposing the substrate to a metal precursor other than a titanium-containing precursor to form a metal silicide layer; and
subsequent to exposing the substrate to the metal precursor, cyclically exposing the substrate to a titanium-containing precursor, a nitrogen-containing precursor and a silicon-containing precursor to form a titanium silicon nitride (TiSiN) layer.

2. A method of forming a diffusion barrier, the method comprising:
providing a substrate comprising an exposed silicon surface;
converting the exposed silicon surface into a metal silicide layer other than a titanium silicide layer in a reactor; and
subsequent to converting the exposed silicon surface into the metal silicide layer, forming a titanium silicon nitride (TiSiN) layer over the metal silicide layer in situ in the reactor.

3. A method of forming a diffusion barrier, the method comprising:
providing a substrate comprising an exposed silicon surface;
exposing the substrate to a metal precursor other than a titanium-containing precursor at a temperature sufficient to cause conversion of the exposed silicon surface into a metal silicide layer other than a titanium silicide layer; and
subsequent to forming the metal silicide layer, forming a titanium silicon nitride (TiSiN) layer directly on the metal silicide layer.

4. A method of forming a diffusion barrier, the method comprising:
providing a substrate comprising a silicon region and a dielectric region;
selectively forming a metal silicide layer, other than a titanium silicide layer, over the silicon region by exposing an exposed surface of the silicon region to a metal precursor other than a titanium-containing precursor; and
subsequent to forming the metal silicide layer, forming a titanium silicon nitride (TiSiN) layer on the metal silicide layer.

5. The method of Embodiment 1, wherein exposing the substrate to the metal precursor in a reactor converts the exposed silicon surface into a metal silicide layer other than a titanium silicide layer, and wherein cyclically exposing the substrate is performed in situ in the reactor to form a TiSiN layer over the metal silicide layer.

6. The method of Embodiment 1, wherein exposing the substrate to the metal precursor comprises exposing the substrate to the metal precursor at a temperature sufficient to cause conversion of the exposed silicon surface into a metal silicide layer other than a titanium silicide layer, and wherein cyclically exposing the substrate forms a TiSiN layer directly on the metal silicide layer.

7. The method of Embodiment 1, wherein the substrate comprises a silicon region and a dielectric region, the silicon region comprising the exposed silicon surface, wherein exposing the exposed silicon surface of the silicon region to the metal precursor selectively forms a metal silicide layer other than a titanium silicide layer over the silicon region, and wherein cyclically exposing the substrate forms a TiSiN layer on the metal silicide layer.

8. The method of Embodiment 2, wherein converting the exposed silicon surface into the metal silicide layer comprises exposing the substrate to a metal precursor other than a titanium-containing precursor, and wherein forming the TiSiN layer comprises cyclically exposing the substrate to a titanium-containing precursor, a nitrogen-containing precursor and a silicon-containing precursor.

9. The method of Embodiment 2, wherein converting the exposed silicon surface into the metal silicide layer comprises exposing the substrate to a metal precursor other than a titanium-containing precursor at a temperature sufficient to cause conversion of the exposed silicon surface into the metal silicide layer, and wherein the TiSiN layer is formed directly on the metal silicide layer.

10. The method of Embodiment 2, wherein the substrate comprises a silicon region and a dielectric region, the silicon region comprising the exposed silicon surface, and wherein converting the exposed silicon surface into the metal silicide layer comprises selectively forming the metal silicide layer over the silicon region by exposing the exposed silicon surface to a metal precursor other than a titanium-containing precursor.

11. The method of Embodiment 3, wherein forming the TiSiN layer comprises cyclically exposing the substrate to a titanium-containing precursor, a nitrogen-containing precursor and a silicon-containing precursor.

12. The method of Embodiment 3, wherein forming the TiSiN layer is performed in situ in a same reactor as exposing the substrate to the metal precursor.

13. The method of Embodiment 3, wherein the substrate comprises a silicon region and a dielectric region, the silicon region comprising the exposed silicon surface, and wherein conversion of the exposed surface into the metal silicide layer comprises selectively forming the metal silicide layer over the silicon region of the substrate.

14. The method of Embodiment 4, wherein forming the TiSiN layer comprises cyclically exposing the substrate to a titanium-containing precursor, a nitrogen-containing precursor and a silicon-containing precursor.

15. The method of Embodiment 4, wherein forming the TiSiN layer is performed in situ in a same reactor as selectively forming the metal silicide layer.

16. The method of Embodiment 4, wherein selectively forming the metal silicide layer comprises exposing the substrate to a metal precursor other than a titanium-containing precursor at a temperature sufficient to cause conversion of an exposed silicon surface of the silicon region into the metal silicide layer, and wherein the TiSiN layer is formed directly on the metal silicide layer.

17. The method of any one of Embodiments 1 and 3-16, wherein the metal precursor is a tungsten-containing precursor, and the metal silicide layer is a tungsten silicide layer.

18. The method of any one of Embodiments 1 and 3-17, wherein the metal precursor is a molybdenum-containing precursor, and the metal silicide layer is a molybdenum silicide layer.

19. The method of any one of Embodiments 1 and 3-17, wherein the metal precursor is a vanadium-containing precursor, and the metal silicide layer is a vanadium silicide layer.

20. The method of any one Embodiments 1 and 3-17, wherein the metal precursor is a hafnium-containing precursor, and the metal silicide layer is a hafnium silicide layer.

21. The method of any one of Embodiments 1 and 3-17, wherein the metal precursor is a niobium-containing precursor, and the metal silicide layer is a niobium silicide layer.

22. The method of any one of Embodiments 1 and 3-17, wherein the metal precursor is a zirconium-containing precursor, and the metal silicide layer is a zirconium silicide layer.

23. The method of any one of the above Embodiments, wherein the metal silicide layer is formed without exposing the substrate to a silicon-containing precursor.

24. The method of any one of the above Embodiments, wherein the metal silicide layer is formed in part by deposition of a metal by chemical vapor deposition.

25. The method of any one of the above Embodiments, wherein forming the TiSiN layer is performed by cyclically exposing the substrate to non-overlapping pulses of a titanium-containing precursor, a nitrogen-containing precursor and a silicon-containing precursor.

26. The method of any one of the above Embodiments, wherein forming the TiSiN layer is performed by atomic layer deposition.

27. The method of method of any one of the above Embodiments, wherein the exposed silicon surface comprises a single crystalline silicon surface.

28. The method of method of any one of the above Embodiments, wherein the exposed silicon surface comprises a polycrystalline silicon surface.

29. The method of any one of the above Embodiments, wherein the diffusion barrier comprises no intervening layer between the exposed silicon surface and the metal silicide layer.

30. The method of any one of the above Embodiments, wherein the diffusion barrier comprises no intervening layer between the metal silicide layer and the TiSiN layer.

31. The method of any one of the above Embodiments, wherein the substrate comprises the exposed silicon surface in a trench formed through a dielectric layer over the substrate.

32. The method of any one of the above Embodiments, wherein the substrate comprises the exposed silicon surface in a via formed through a dielectric layer over the substrate.

33. The method of any one of the above Embodiments, further comprising forming a tungsten layer over the TiSiN layer.

34. The method of any one of the above Embodiments, wherein the metal silicide layer is formed using a metal fluoride precursor or a metal chloride precursor.

35. The method of any one of the above Embodiments, wherein the metal silicide layer is formed using a metal halide precursor and a silicon-containing precursor.

36. The method of any one of the above Embodiments, wherein the metal silicide layer is formed using a metal halide precursor and hydrogen gas.

37. The method of any one of the above Embodiments, wherein the metal silicide is formed using a metal halide precursor, hydrogen gas, and silane (SiH₄) or disilane (SiH₆) gas.

38. The method of any one of the Embodiments, wherein the metal silicide layer is formed by exposing the substrate to the metal precursor for a time duration that is sufficient for conversion of a silicon surface into the metal silicide while being insufficient for forming a metal layer formed of the metal of the metal precursor.

39. The method of Embodiment 17, wherein the tungsten-containing precursor comprises WF₆.

40. The method of Embodiment 18, wherein the molybdenum-containing precursor comprises 2MoCl₅.

41. The method of Embodiment 19, wherein the vanadium-containing precursor comprises VCl₄.

42. The method of Embodiment 20, wherein the hafnium-containing precursor comprises HfCl₄.

43. The method of Embodiment 21, wherein the niobium-containing precursor comprises NbCl₄.

44. The method of Embodiment 22, wherein the zirconium-containing precursor comprises ZrCl₄.

45. The method of any one of the above Embodiments, wherein the exposed silicon surface has a (001) crystal orientation.

46. The method of any one of the above Embodiments, wherein forming the metal silicide layer further comprises exposing the substrate to a silicon-containing precursor.

47. The method of any one of the above Embodiments, wherein the metal silicide layer does not form on the dielectric region.

48. The method of any one of the above Embodiments, wherein the substrate comprises doped polysilicon regions, and forming the metal silicide layer comprises forming a Schottky barrier at an interface between the doped polysilicon regions and the metal silicide layer.

49. The method of any one of the above Embodiments, wherein the TiSiN layer is formed using the titanium-containing precursor comprises TiCl₄.

50. The method of any one of the above Embodiments, wherein the TiSiN layer is formed using the nitrogen-containing precursor is NH₃.

51. The method of any one of the above Embodiments, wherein the TiSiN layer is formed using the silicon-containing precursor selected from the group consisting of SiH₄, Si₂H₆, SiH₂Cl₂, SiH₃Cl, Si₂Cl₆ and Si₃Cl₈.

52. The method of any one of the above Embodiments, wherein the diffusion barrier comprises a titanium silicon nitride layer having a silicon concentration exceeding 5 atomic %.

53. The method of any one of the above Embodiments, wherein the diffusion barrier comprises a titanium silicon nitride layer having a silicon concentration of 5-30 atomic %.

54. The method of any one of the above Embodiments, wherein the diffusion barrier formed using the method has a resistivity of 5000 μΩ·cm or lower.

55. The method of any one of the above Embodiments, wherein the diffusion barrier formed using the method has a resistivity of 2000 μΩ·cm or lower.

56. The method of any one of the above Embodiments, wherein the diffusion barrier has a thickness of 13 nm or lower.

57. The method of any one of the above Embodiments, wherein exposing the substrate to the tungsten-containing precursor comprises exposing at a pressure in the reactor of 1-380 torr.

58. The method of any one of the above Embodiments, wherein exposing the substrate to the tungsten-containing precursor is performed at a substrate temperature of 200° C. to 800° C.

59. The method of any one of the above Embodiments, wherein exposing the substrate to the tungsten-containing precursor is performed at a substrate temperature of 300° C. to 700° C.

60. The method of any one of the above Embodiments, wherein the metal silicide layer and the TiSiN layer is formed at a constant substrate temperature.

61. The method of any one of the above Embodiments, wherein the substrate undergoes rapid thermal annealing.

62. The method of any one of the above Embodiments, wherein one or both of the metal silicide layer and the TiSiN layer are formed without aid of a plasma.

63. A diffusion barrier structure comprising:
a substrate comprising a silicon region;
a metal silicide layer other than a titanium silicide on the silicon region; and
a titanium silicon nitride (TiSiN) layer on the metal silicide layer.

64. The diffusion barrier structure of Embodiment 63, wherein the silicon region comprises polycrystalline silicon.

65. The diffusion barrier structure of Embodiment 63, wherein the silicon region is a single crystal silicon region.

66. The diffusion barrier structure of Embodiment 63 or 64, wherein the silicon region has a (001) crystal orientation.

67. The diffusion barrier structure of any one of Embodiments 63-66, wherein the metal silicide layer comprises any one of the metals selected from the group consisting of tungsten, molybdenum, vanadium, hafnium, niobium, and zirconium.

68. The diffusion barrier structure of any one of Embodiments 63-67, further comprising a tungsten layer on the TiSiN layer.

69. The diffusion barrier structure of any one of Embodiments 63-68, wherein a combined thickness of the metal silicide layer and the TiSiN layer does not exceed 13 nm.

70. The diffusion barrier structure of any one of Embodiments 63-69, wherein the diffusion barrier structure comprises no intervening layer between the metal silicide layer and the silicon region.

71. The diffusion barrier structure of any one of Embodiments 63-70, wherein the diffusion barrier structure comprises no intervening layer between the metal silicide layer and the TiSiN layer.

72. The diffusion barrier structure of any one of Embodiments 63-71, wherein the silicon region is formed adjacent to a dielectric film formed on the substrate.

73. The diffusion barrier structure of any one of Embodiments 63-72, wherein the silicon region is formed in a trench formed through a dielectric layer over the substrate.

74. The diffusion barrier structure of any one of Embodiments 63-73, wherein the silicon region is formed in a via formed through a dielectric layer over the substrate.

75. The diffusion barrier structure of any one of Embodiments 63-74, wherein the metal silicide layer is formed by silicidation of the silicon region such that the metal silicide extends vertically below a major surface of the substrate on which the diffusion barrier structure is formed.

76. The diffusion barrier structure of any one of Embodiments 63-75, wherein the metal silicide layer is formed by deposition on the silicon region such that an interface between the metal silicide and the silicon region is substantially at a same vertical level as that of a major surface of the substrate on which the diffusion barrier structure is formed.

Although the present invention has been described herein with reference to the specific embodiments, these embodiments do not serve to limit the invention and are set forth for illustrative purposes. It will be apparent to those skilled in the art that modifications and improvements can be made without departing from the spirit and scope of the invention.

Such simple modifications and improvements of the various embodiments disclosed herein are within the scope of the disclosed technology, and the specific scope of the disclosed technology will be additionally defined by the appended claims.

In the foregoing, it will be appreciated that any feature of any one of the embodiments can be combined or substituted with any other feature of any other one of the embodiments.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while features are presented in a given arrangement, alternative embodiments may perform similar functionalities with different components and/or sensor topologies, and some features may be deleted, moved, added, subdivided, combined, and/or modified. Each of these features may be implemented in a variety of different ways. Any suitable combination of the elements and acts of the various embodiments described above can be combined to provide further embodiments. The various features and processes described above may be implemented independently of one another, or may be combined in various ways. All possible combinations and subcombinations of features of this disclosure are intended to fall within the scope of this disclosure.

What is claimed is:

1. A method of forming a diffusion barrier, the method comprising:
providing a substrate comprising an exposed silicon surface;
forming a metal silicide layer, other than a titanium silicide layer, by exposing the substrate to a metal precursor other than a titanium-containing precursor; and
subsequent to forming the metal silicide layer, forming a titanium silicon nitride (TiSiN) layer by cyclically exposing the substrate to a titanium-containing precursor, a nitrogen-containing precursor, and a silicon-containing precursor.

2. The method of claim 1, wherein the metal precursor comprises any one of a tungsten-containing precursor, a molybdenum-containing precursor, a vanadium-containing precursor, a hafnium-containing precursor, a niobium-containing precursor, or a zirconium-containing precursor, and wherein the metal silicide layer comprises a corresponding one of a tungsten silicide, a molybdenum silicide, a vanadium silicide, a hafnium silicide, a niobium silicide, or a zirconium silicide.

3. The method of claim 1, wherein the metal precursor comprises a metal halide precursor.

4. The method of claim 3, wherein forming the metal silicide layer further comprises exposing the substrate to hydrogen gas.

5. The method of claim 3, wherein forming the metal silicide layer further comprises exposing the substrate to a silicon-containing precursor.

6. The method of claim 1, wherein the TiSiN layer is formed directly on the metal silicide layer.

7. The method of claim 1, wherein the TiSiN layer is formed in situ in a same reactor as the metal silicide layer.

8. The method of claim 1, wherein the exposed silicon surface has a (001) crystal orientation.

9. The method of claim 1, wherein the substrate further comprises a dielectric region and forming the metal silicide layer comprises selectively forming the metal silicide layer on the exposed silicon surface of the substrate.

10. The method of claim 1, wherein forming the diffusion barrier further comprises annealing.

11. A method of forming a diffusion barrier, the method comprising:
providing a substrate comprising a silicon region and a dielectric region;
selectively forming a metal silicide layer, other than a titanium silicide layer, over the silicon region by exposing an exposed surface of the silicon region to a metal precursor other than a titanium-containing precursor; and
subsequent to forming the metal silicide layer, forming a titanium silicon nitride (TiSiN) layer on the metal silicide layer.

12. The method of claim 11, wherein the metal precursor comprises any one of a tungsten-containing precursor, a molybdenum-containing precursor, a vanadium-containing precursor, a hafnium-containing precursor, a niobium-containing precursor, or a zirconium-containing precursor and the metal silicide layer comprises a corresponding one of tungsten silicide, molybdenum silicide, vanadium silicide, hafnium silicide, niobium silicide, or zirconium silicide.

13. The method of claim 11, wherein the metal precursor comprises a metal halide precursor.

14. The method of claim 13, wherein forming the metal silicide layer further comprises exposing the substrate to hydrogen gas.

15. The method of claim 13, wherein forming the metal silicide layer further comprises exposing the substrate to a silicon-containing precursor.

16. The method of claim 11, wherein the TiSiN layer is formed directly on the metal silicide layer.

17. The method of claim 11, wherein the TiSiN layer is formed in situ in a same reactor as the metal silicide layer.

18. The method of claim 11, wherein the exposed silicon surface has a (001) crystal orientation.

19. The method of claim 11, wherein forming the TiSiN layer comprises cyclically exposing the substrate to a titanium-containing precursor, a silicon-containing precursor, and a nitrogen-containing precursor.

20. The method of claim 11, wherein forming the diffusion barrier further comprises an annealing step.
